(19) United States
(12) Patent Application Publication
(10) Pub. No.: US 2006/0138392 A1
(43) Pub. Date: Jun. 29, 2006

(54) Mild methods for generating patterned silicon surfaces

(76) Inventors: Ned B. Bowden, Iowa City, IA (US); Samrat Dutta, Iowa City, IA (US)

Correspondence Address: Schwegman, Lundberg, Woessner & Kluth, P.A., P.O. Box 2938, Minneapolis, MN, 55402, US

(21) Appl. No.: 11/259,756

(22) Filed: Oct. 26, 2005

Related U.S. Application Data
(60) Provisional application No. 60/623,080, filed on Oct. 28, 2004.

(51) Int. Cl. H01L 47/00

(52) U.S. Cl. 257/1

(57) ABSTRACT

The invention provides methods for making self-assembling monolayers on silicon surfaces using mild conditions.

This application claims benefit of the filing date of U.S. Provisional Ser. No. 60/623,080, filed Oct. 28, 2004, the contents of which are incorporated herein by reference.

### FIELD OF THE INVENTION

The invention provides mild procedures for developing organized patterns on silicon surfaces. The methods involve mild conditions, are easy to perform and permit patterning of biological molecules on the silicon surface. Hence, the invention allows integration of biological molecules and systems into current semiconductor, sensor and other nanotechnology devices.

### BACKGROUND OF THE INVENTION

Microarray and/or microchip technologies permit detection of minute molecular interactions without the need to extensively purify the reactants and products of the reactions monitored. Photolithography, mechanical-spotting methods, inkjet methods, and the like have been used for manufacturing such microarrays, microchips and biosensors. See, e.g., Trends in Biotechnology, 16: 301-306 (1998).

However, techniques for integrating biology and nanotechnology using silicon are lacking due to the harsh conditions used to assemble molecular patterns on silicon. Current method for molecular patterning on silicon involve the use of ultraviolet light, Lewis acids, electrochemistry, organic radicals from the decomposition of diacyl peroxides at elevated temperatures, heat or halogenation of the surface followed by Grignard reagents. Such conditions can destroy or alter the properties of complex biological molecules.

New, milder methods are needed to facilitate manufacture of silicon monolayers patterned with complex biological molecules.

### SUMMARY OF THE INVENTION

The invention provides methods for making ordered, patterned, organic self-assembled monolayers (SAMs) on hydrogen-terminated silicon surfaces using a sterically-hindered free radical source. Examples of sterically-hindered free radical sources include 2,2,6,6-tetramethyl-1-piperidinyloxy (TEMPO), TEMPO-like molecules and derivatives thereof.

Thus, one aspect of the invention is an ordered, layered silicon surface made by a method that involves obtaining a silicon surface comprising hydrogen-terminated silicon, and reacting the silicon surface with an anchor molecule in the presence of a sterically-hindered free radical source under conditions sufficient to link the anchor molecule to the silicon surface.

Another aspect of the invention is a method that involves obtaining a silicon surface comprising hydrogen-terminated silicon, and reacting the silicon surface with an anchor molecule in the presence of a sterically-hindered free radical source under conditions sufficient to link the anchor molecule to the silicon surface.

Another aspect of the invention is a coated or layered silicon surface made as described herein. Thus, for example, the invention provides a layered silicon surface comprising hydrogen-terminated silicon and at least one ordered monolayer of anchor molecules, wherein the ordered monolayer on the silicon surface has a contact angle of water that is at least 100°. In some embodiments, the contact angle of water is at least 103°. In other embodiments, the contact angle of water is at least 105°. In other embodiments, the contact angle of water is at least 107°. In other embodiments, the contact angle of water is at least 110°. In other embodiments, the contact angle of water is at least 112°.

The invention also provides processes, sterically-hindered free radical sources, and intermediates useful for the preparation of coated or layered silicon surfaces. The methods, processes, free radical sources and intermediates of the invention can be used to create patterned composite structures on a surface via layer-by-layer deposition of thin films.

### DESCRIPTION OF THE FIGURES

FIG. 1A illustrates a method of the invention for layering a hydrogen-terminated silicon surface, such as a Si(111)-H surface, with an ordered layer of anchor molecules. A hydrogen-terminated silicon surface is generated by reacting a clean silicon wafer with 40% NH₄F under gaseous nitrogen. In this illustration, the surface is reacted with different concentrations of a sterically hindered free radical source (e.g., TEMPO or derivatives of TEMPO) in the presence of 1-octadecene to form a monolayer. Well-ordered monolayers form on Si(111) surfaces with one carbon-silicon bond per two silicon hydride bonds. Excess silicon hydride bonds remain on the surface even after the assembly of a crystalline self-assembled monolayer.

FIG. 1B shows examples of sterically hindered free radical sources (e.g., TEMPO or derivatives of TEMPO) that can be used in the method illustrated in FIG. 1A.

FIGS. 2-11 provide representative X-ray photoelectron spectra of various monolayers produced as described in Table 1. FIGS. 2-6 show X-ray photoelectron spectra of entry 3 in Table 1, while FIGS. 7-11 show X-ray photoelectron spectra of entry 7 in Table 1.

FIG. 12 illustrates a method of the invention for assembling and functionalizing olefin-terminated monolayers by cross metathesis. A silicon wafer with a native layer of SiOₓ was cleaned and then placed in Ar purged 40% H₄NF for 30 min to form a hydrogen-terminated Si(111) surface. The wafer was immediately immersed in a solution of A, 1-octadecene, and trace amounts of TEMPO-C₁₀ for 24 h. Cross metathesis between olefin-terminated monolayers and olefins with different “R” groups including carboxylic acids, alcohols, bromides, and aldehydes was catalyzed by the ruthenium-based Grubbs' first generation catalyst.

FIG. 13A shows a method for patterning olefin-terminated monolayers on Si(111) with the Grubbs' catalyst. First, a mixed monolayer of A and 1-octadecene was assembled. The silicon wafer was immersed in a solution of the Grubbs' first generation catalyst for 15 min. The Grubbs' catalyst attached to the monolayer by cross metathesis with an olefin on the surface. A PDMS stamp was then placed on the monolayer to form microfluidic channels on the surface. Next, a solution of an olefin filled the channels by an external syringe (not shown). Monolayers in contact with PDMS were not exposed to the olefins and did not react. After 15 to 30 min the channels were rinsed, the PDMS stamp was removed and turned 90° before being placed on the monolayer again. A new solution of an olefin added to the channels. Finally, the channels were rinsed, the PDMS stamp was removed, and the silicon wafer was rinsed.

FIG. 13B provides a SEM micrograph of crossed brush polymers synthesized as described in FIG. 13B.

FIG. 13C and 13D provide scanning electron microscopy (SEM) micrographs of monolayers reacted by cross metathesis with CH₂═CH(CH₂)₈CO₂H to expose acids along the surface. In these experiments CH₂═CH(CH₂)₈CO₂H was added to the microchannels rather than 5-norbornene-2-carboxylic acid. The image in FIG. 13D is a close-up of the image in FIG. 13C.

### DETAILED DESCRIPTION OF THE INVENTION

The invention provides methods of generating organized patterns of anchor molecules on hydrogen-terminated silicon surfaces. Complex biological molecules, ligands, linkers, reactive groups, and combinations thereof can be layered and/or patterned on the ordered layer of anchor molecules. The methods of the invention generally involve obtaining a silicon surface comprising hydrogen-terminated silicon, reacting the silicon surface with an anchor molecule in the presence of sterically-hindered free radical source under conditions sufficient to link the anchor molecule to the silicon surface. One example of a hydrogen-terminated silicon is a silicon where substantial amounts or numbers of oxygen atoms are replaced by hydrogen atoms. In some embodiments, the silicon is Si(111), or Si(111)-H.

Sterically-hindered free radical sources include any source of a free radical that can provide an ordered layer of alkanes on a hydrogen-terminated silicon surface. In some embodiments the sterically-hindered free radical source provides an ordered layer of alkanes with an advancing contact angle of water that is about 105° or greater, about 107° or greater, about 108° or greater, about 109° or greater, about 110° or greater, about 111° or greater, about 112° or greater, about 113° or greater, about 114° or greater, or about 115° or greater.

For example, such sterically-hindered free radical sources include molecules that have at least one unpaired electron, where the unpaired electron(s) is surrounded by two or more substituents. Examples of sterically-hindered free radical sources include 2,2,6,6-tetramethyl-1-piperidinyloxy (TEMPO), TEMPO-like molecules and derivatives thereof. Thus, for example, TEMPO and TEMPO derivatives that can be used in the methods of the invention can have the following formula:

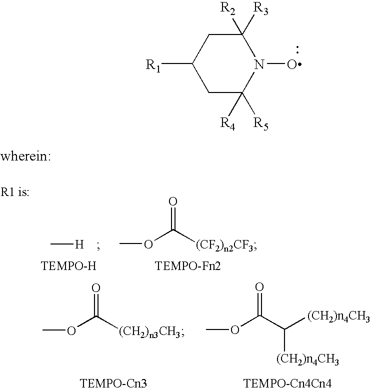

R₂, R₃, R₄ and R₅ are separately lower alkyl;

n1 is an integer of 1 to 20;

n2 is an integer of 1 to 20;

n3 is an integer of 1 to 20; and

each n4 is separately an integer of 1 to 20.

In some embodiments, any one of n1, n2, n3 or n4 can be an integer of from 2-15, or an integer of from 3-10, or any other value between 1 and 20.

Anchor molecules that can be used in the methods and monolayers of the invention include, for example, alkanes, alkenes, alkanethiols, alkenethiols, ethers, diolefins, oligo(ethylene)glycols, and combinations thereof. The anchor molecules can have reactive groups, protecting groups or leaving groups that can interact or bond with, or be replaced by, a moiety of a ligand molecule to be attached to the anchor molecule. Selected ligand molecules such as polypeptides, nucleic acids (RNA and DNA), peptides, peptidomimetics, antibodies, antigens, receptors, receptor ligands, small molecules, drugs and the like can be linked to the anchor molecules either directly or indirectly through convenient moieties and/or linkers.

A pattern of anchor molecules or selected ligand molecules can be generated on the silicon surface by blocking the reaction of anchor molecules in selected areas of the silicon surface to generate a pattern of anchor molecules on the silicon surface, by soft lithography or by linking selected ligand molecules to selected regions of the lawn of anchor molecules bound to the silicon surface. Layers of anchor, linker and ligand molecules can be patterned on the silicon surface. Such layers can be generated by adding and later removing protecting groups, placing leaving groups on selected reactive sites in anchor, ligand and linker molecules, etc. within selected regions of the silicon surface.

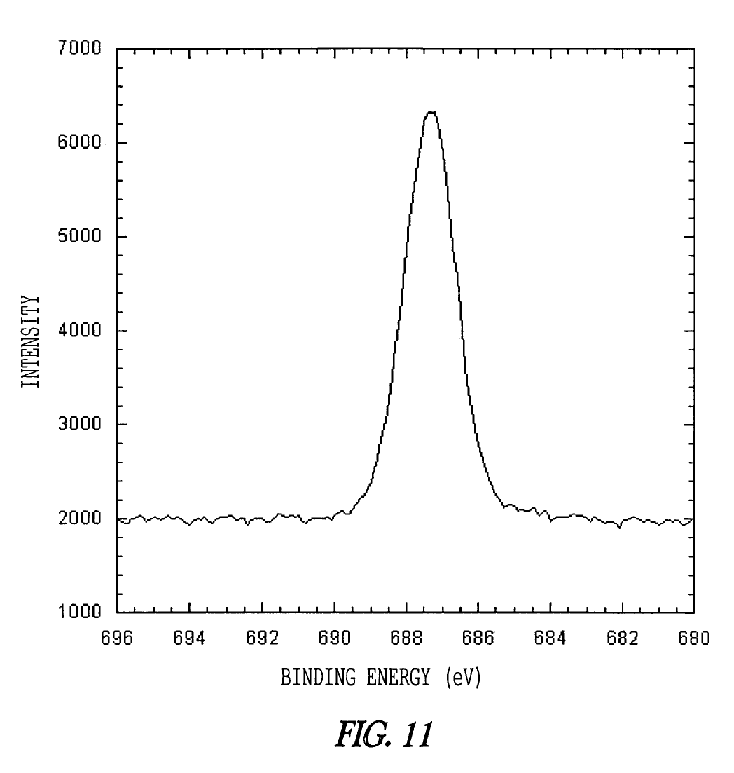

In some embodiments, the anchor molecules are olefins or a combination of olefins, ether diolefins or other types of anchor molecules. Hydrogen-terminated silicon (e.g., Si(111)-H) is tolerant of the olefin functional group and these olefins provide a useful functional group for further functionalization through the following cross metathesis reaction. 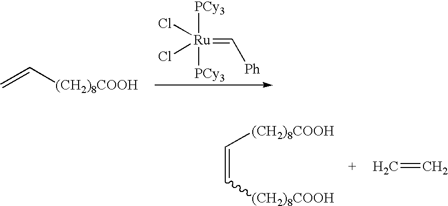
Cross metathesis is a simple reaction, the reaction between two terminal-olefins results in the formation of a double bond and the release of ethylene (see FIG. 12). The release of ethylene can be used to drive this reaction to quantitative conversions. The catalyst shown above is benzylidene-bis(tricyclohexylphosphine)dichlororuthenium (also called Grubbs' first generation catalyst, available from Sigma-Aldrich). This catalyst is less sensitive to functional groups than catalysts based on Ti, Mo, and W, it catalyzes cross metathesis reactions at low catalyst loadings, and it is over four times less expensive than the Grubbs' second generation catalyst. This catalyst has been used to carry out cross metathesis reactions between proteins, carbohydrates, crown ethers, and numerous small molecules displaying acids, halides, alcohols, esters, amides, and amines.

Thus, the invention provides method for generating organized patterns of anchor molecules on hydrogen-terminated silicon.

### DEFINITIONS

Unless stated otherwise, the following terms and phrases as used herein are intended to have the following meanings:

As used herein an advancing contact angle of water, or contact angle of water, is a quantitative measure of the wetting of a solid by a liquid. It is defined geometrically as the angle formed by a liquid droplet on a solid surface. Thus, when the liquid (e.g., water) does not wet the solid, the droplet does not spread out onto the surface and tends to forms a larger contact angle. However, when the liquid (e.g., water) does wet the surface, it spreads out and the contact angle is smaller. Thus, high contact angle values indicate poor wetting. In general, if the angle is less than about 90° the liquid is said to wet the solid. If it is greater than about 90° it is said to be non-wetting. A zero contact angle represents complete wetting.

Alkyl, alkoxy, alkenyl, alkynyl, etc. denote both straight and branched groups; but reference to an individual radical such as “propyl” embraces only the straight chain radical, a branched chain isomer such as “isopropyl” being specifically referred to.

“Alkyl” is a hydrocarbon having up to 25 carbon atoms. Alkyls can be branched or unbranched radicals, for example methyl, ethyl, propyl, isopropyl, n-butyl, sec-butyl, isobutyl, tert-butyl, 2-ethylbutyl, n-pentyl, isopentyl, 1-methylpentyl, 1,3-dimethylbutyl, n-hexyl, 1-methylhexyl, n-heptyl, isoheptyl, 1,1,3,3-tetramethylbutyl, 1-methylheptyl, 3-methylheptyl, n-octyl, 2-ethylhexyl, 1,1,3-trimethylhexyl, 1,1,3,3-tetramethylpentyl, nonyl, decyl, undecyl, 1-methylundecyl, dodecyl, 1,1,3,3,5,5-hexamethylhexyl, tridecyl, tetradecyl, pentadecyl, hexadecyl, heptadecyl, octadecyl, icosyl or docosyl.

“Alkenyl” is an alkyl with at least one site of unsaturation, i.e. a carbon-carbon double bond.

“Alkene” or “olefin” is a hydrocarbon having 2 to 25 carbon atoms and at least one double bond. In some embodiments, the alkene or olefin has a terminal double bond.

“Alkylene” is a saturated, branched or straight chain or cyclic hydrocarbon radical of 1-25 carbon atoms. An alkylene has two monovalent radical centers derived by the removal of two hydrogen atoms from the same or two different carbon atoms of a parent alkane. Examples of alkylenes include methylene, ethylene, propylene, trimethylene, tetramethylene, pentamethylene, hexamethylene, heptamethylene, octamethylene, decamethylene, dodecamethylene or octadecamethylene.

Lower alkyl is an alkyl having 1 to 6 carbon atoms.

Suitable leaving groups include, for example, halogens such as fluorine, chlorine, bromine and iodine, sulfonyl halides, aryl-sulfonyl halides (e.g., tosyl-halides), alkyl-sulfonyl halides (e.g., methane sulfonyl halide), halo-alkyl-sulfonyl halides (e.g., trifluoroethane sulfonyl halides), halopyrimidines (e.g., 2-fluoro-1-methylpyridinium toluene-4-sulfonate), triflate and the like.

“Linker” refers to a chemical moiety comprising a covalent bond or a chain or group of atoms that covalently attaches a desired molecule to another molecule, such as an anchor molecule or to a silicon surface. Linkers include repeating units of alkyloxy (e.g., polyethylenoxy, PEG, polymethyleneoxy) and alkylamino (e.g., polyethyleneamino, Jeffamine™); and diacid ester and amides including succinate, succinamide, diglycolate, malonate, and caproamide.

“Protecting group” refers to a moiety of a compound that masks or alters the properties of a functional group or the properties of the compound as a whole. Chemical protecting groups and strategies for protection/deprotection are well known in the art. See e.g., Protective Groups in Organic Chemistry, Theodora W. Greene, John Wiley & Sons, Inc., New York, 1991. Protecting groups are often utilized to mask the reactivity of certain functional groups, to assist in the efficiency of desired chemical reactions, e.g., making and breaking chemical bonds in an ordered and planned fashion. Protection of functional groups of a compound alters other physical properties besides the reactivity of the protected functional group, such as the polarity, lipophilicity (hydrophobicity), and other properties which can be measured by common analytical tools. Chemically protected intermediates may themselves be biologically active or inactive.

When trade names are used herein, applicants intend to independently include the trade name product and the chemical compound or ingredients of the trade name product.

Methods for Binding Organized Anchor Molecules to Silicon Surfaces

The type of silicon employed as a substrate is hydrogen-terminated silicon, i.e. silicon generally or substantially linked to hydrogen atoms rather than, for example, to substantial numbers oxygen atoms. One such hydrogen-terminated silicon is Si(111)-H, which can be obtained in single-side polished Si(111) wafers (n-type) from Silicon Inc, Boise, Idaho. Silicon dioxide is removed from the silicon surface, for example, by treatment with NH₄/HF. The NH₄/HF solution can be a mixture of about 5:1 40% NH₄/48% HF.

A hydrogen-terminated silicon surface, for example, a Si(111)-H surface is generated by treatment with 40% NH₄F under an atmosphere of an inert gas such as argon. Prior to generating the hydrogen-terminated silicon surface, the silicon surface is cleaned, silicon dioxide is removed from the silicon surface as described above and then a thin layer of silicon dioxide is grown on the silicon surface by treating the silicon with hydrogen peroxide and concentrated sulfuric acid at slightly elevated temperatures (e.g., about 70° C. to about 100° C., preferably about 90° C.). Procedures for generating a hydrogen-terminated silicon surface are described, for example, in Wade et al. APPL. PHYS. LETT. 71: 1679-81 (1997) and Higashi et al. APPL. PHYS. LETT 56: 656-658 (1990). The silicon surface(s) can be dried under a stream of gaseous nitrogen.

Mild conditions can be used for linking anchor molecules to the hydrogen-terminated silicon surfaces. The hydrogen-terminated silicon surfaces are contacted with a solution of the selected anchor molecule (e.g. 1-octadecene and/or a diolefin such as —CH₂═CH(CH₂)₉O(CH₂)₉CH═CH₂—) in the presence of a sterically-hindered free radical source (e.g., as illustrated herein TEMPO or a TEMPO derivative). Linking the anchor molecules to the hydrogen-terminated silicon surface is done at room temperature under gaseous nitrogen for about 5 hours to about 48 hours, about 7 hours to about 36 hours, or about 24 hours. The silicon surface is then washed with a solvent such as hexane, acetone, and/or methanol. The silicon surface can be further cleaned with dichloromethane or other suitable solvent.

In some embodiments, small wafers or chips of silicon can be used. When such wafers or chips are employed the entire wafer or chip can be immersed in a solution of anchor and a sterically-hindered free radical source, then immersed in solvent washing solution and even sonicated to remove solvents and unreacted molecules.

As illustrated herein such treatment generates a lawn of organized anchor molecules on the silicon surface. The presence of an ordered layer of anchor molecules on a silicon surface can be detected by determining what the advancing contact angle of water is for the layered silicon surface. Surfaces with contact angles of more than 90° are generally considered to resist wetting and/or repel water. As described herein, layered silicon surfaces contact angles of more than 95° or more than 100° have ordered layers of anchor molecules. In some embodiments, the layered silicon surfaces of the invention have a contact of water that is about 105° or greater, about 107° or greater, about 108° or greater, about 109° or greater, about 110° or greater, about 111° or greater, about 112° or greater, about 113° or greater, about 114° or greater, or about 115° or greater.

Protected or even non-protected functional groups can be present on the anchor molecules to permit attachment of selected ligands to the silicon surface. Such functional groups can be any chemical moiety that can react with a selected ligand. For example, the functional group can be a carboxyl, carboxylate, hydroxyl, oxygen, thio, or amino group. Protecting groups for these functional groups are available in the art. Removal of protecting groups from selected functional groups or from selected anchor molecules (e.g. those anchor molecules in one or more regions of the silicon surface), permits attachment of selected ligands to some anchor molecules but not to others.

Cross metathesis between olefin-terminated anchor monolayers can be used to generate functional groups and attachment sites for different ligands or to directly attach a selected ligand as shown in FIG. 12. Using such a cross metathesis reaction, different functional groups can be added to the anchor molecules including carboxylic acids, alcohols, bromides, and aldehydes. This is one way to generate a pattern of selected ligands on the silicon surface. Additional procedures for generating patterns of selected ligands on silicon surfaces are described below.

Generating Patterns of Selected Ligands on Silicon Surfaces

Any method available to one of skill in the art can be used to generate a pattern of selected ligands on the silicon surfaces of the invention. Such methods include, for example, microcontact printing, using ultraviolet light and an optical mask to oxidize selectively molecules on the silicon surface, etching with light, electrons of an e-beam microscope or electrons of a scanning tunneling microscope to locally disrupt molecules in or on the silicon surface, soft lithography and similar procedures.

Microcontact printing utilizes an inked, micropatterned stamp to print chemicals or biomolecules onto a silicon substrate of the invention. Microcontact printing has been used to print alkanethiols onto Au, Ag or Cu substrates to form a self-assembled monolayer (SAM) in the regions of contact between the stamp and the substrate. Similar methods can be used for printing on the silicon substrates of the invention.

The stamp employed is generally made from an elastomer such as polydimethylsiloxane (PDMS). PDMS polymers are commercially available under the trademark Sylgard (e.g. Sylgard 182, 184 and 186) manufactured by the Dow Corning Company, Midland, Mich. The PDMS stamp is replicated from a mold (typically a silicon wafer having a photoresist pattern formed thereon). The PDMS stamp is inked with a solution of SAM-forming molecules and dried to remove the solvent used to prepare the ink. The stamp is then placed onto the substrate to form a SAM in the printed regions of the substrate. It is possible to use the printed SAM as a patterned resist layer for selectively etching a substrate. In this case, the printed SAM protects the substrate from dissolution in an etch bath. A relatively thin SAM can protect a substrate from dissolution in a wet etch bath provided that it has a good order and density over the substrate and that the etch bath is selective.

For example, methods similar to those used for patterning of a gold substrate using a SAM of hexadecanethiol and a cyanide-containing etch bath can be employed with the present silicon substrates. Such methods involve, for example, placing 0.5 ml of a 0.2 mM solution of hexadecanethiol in ethanol onto the surface a 1 cm² patterned PDMS stamp. The solution is left on the stamp for 30 s and then blown away with a stream of nitrogen. The stamp is dried with the stream of nitrogen and it is placed by hand onto the surface of a gold surface. The contact between the stamp and the substrate enables the transfer of molecules of hexadecanethiol from the stamp to the substrate in the printed areas where the molecules chemisorb to the Au and form a SAM. A typical contact time is 10 s. The stamp is then removed by hand and the printed Au substrate is patterned using a selective wet etch bath: the printed SAM protects the Au from dissolution in an alkaline (pH of 12 or more) solution of water containing potassium cyanide and dissolved oxygen. After etching of the gold in the non printed regions, the patterned gold substrates removed from the bath, rinsed with water and dried. Typical molecules for the ink are hexadecanethiol or eicosanethiol dissolved in ethanol. One of skill in the art can readily adapt such procedures for use with the present silicon substrates.

The present silicon surfaces can be patterned using UV light and an optical mask to oxidize selectively molecules on the silicon surface. In these examples, the oxidized molecules lose their binding capability with the substrate so that they can be washed away from the surface in a subsequent rinsing step (see e.g. Tam-Chang et al., Langmuir 1995, vol. 11, p 4371-4382).

Selected anchor molecules or regions of the silicon substrate itself can be modified or etched with light, electrons of an e-beam microscope or electrons of a scanning tunneling microscope to locally disrupt molecules in or on the silicon surface. The mechanism of interaction between the electrons and the anchor/linker or other molecules forming a monolayer or the silicon substrate can be etched away (see e.g. Lercel et al., J., Vac. Sci. Technol. B 1995, vol. 13, p 1139-1143). In this case, the substrate is etched where the pattern is written. An attempt to pattern surfaces using an inverted process is done by Delamarche et al. (see e.g. Delamarche et al. J. Phys. Chem. B 1998, vol. 102, p 3324-3334). In this approach molecules forming the first SAM are removed using an electron beam instead of ultraviolet light.

Patterning a SAM has also been demonstrated on small length scales using mechanical indentation (see e.g. Abbott et al. Science 1992, vol. 257, p 1380-1382). The blade of a scalpel or the tip of an atomic force microscope or of a scanning tunneling microscope can be used to damage and remove a protective SAM locally. An etching step can then transfer the written pattern into the substrate. The SAM forming material and the overall lithographic processes are of the positive type in this example. It can be desirable to employ an inverted process wherein a mechanical indentation would remove parts of a non-blocking etch SAM and to place an etch-blocking SAM in the indented areas.

Selective deposition can be achieved by introducing alternating regions of two different chemical functionalities on a surface: one which promotes covalent linkage or adsorption; and a second which effectively resists covalent linkage or adsorption on the surface. Protected reactive groups can be used to resist covalent linkage.

Patterning in situ through the use of chemically patterned surfaces as templates for ionic multilayer assembly has been described by Hammond et al., Macromolecules 1995, 28: 7569; Clark et al., Supramol. Sci. 1997, 4, 141-146; Clark et al., Macromol. 1997, 30, 7237-7244; Clark et al., Adv. Mat. 1998, 10, 1515-1519; Clark et al., ACS Polym. Prepr. 1998, 39, 1079-1080; Clark et al., ACS Symp. Ser. 1998, 695, 206-219; and Clark et al., Advanced Materials 1999, 11, 1031-1035.

Alkane thiols and silanes have been used to create functionalized self-assembled monolayers (SAMs) on gold and silicon substrates, respectively, using the micro-contact printing method. Kumar, A.; Biebuyck, H. A.; Whitesides, G. M. Langmuir 1994, 10, 1498-1511; Xia, Y.; Whitesides, G. M. J. Am. Chem. Soc. 1995, 117, 3274-3275; Xia, Y.; Mrksich, M.; Kim, E.; Whitesides, G. M. J. Am. Chem. Soc. 1995, 117, 9576-9577; and Kumar, A.; Whitesides, G. M. Science 1994, 263, 60-62. More recently, other molecular systems such as polymers and ligands have been stamped onto surfaces; in these cases, the molecules were stamped onto a reactive alkanethiolate SAM. Goetting, L. B.; Deng, T.; Whitesides, G. M. Langmuir 1999, 15, 1182-1191; and Lahiri, J.; Ostuni, E.; Whitsides, G. M. Langmuir 1999, 15, 2055-2060. Such methods can readily be adapted for use with the present silicon substrates.

Carbon Nanotubes

The invention also contemplates attachment of carbon nanotubes to the silicon self-assembled monolayers surfaces of the invention and patterns of carbon nanotubes on the silicon self-assembled monolayers of the invention.

Carbon nanotubes were first discovered by Sumio Iijima in 1991 (Nature, 354, pp. 56-58 (1991)). Carbon nanotubes are comprised of carbon, generally in the form of a very long (1-100 microns) hollow tube with a diameter of about 1-100 nm. A wide range of potential applications have been proposed for the carbon nanotube. Such applications include use of carbon nanotubes as electron emitters, battery electrodes, gas separation membranes, sensors and energy storage units. When a multiple of carbon nanotubes are used in these applications, the tubes are preferably aligned in one direction so that their individual features are integrated and assembled into a system in an efficient and easy manner. In general, nanotubes with smaller outside diameters are advantageous for electron emission and improved strength.

Commonly employed methods of producing carbon nanotubes include arc discharge with graphite electrodes, laser sublimation of graphite, and vapor-phase decomposition of carbon compounds using suspended catalytic metal particles. However, many carbon nanotubes produced by these methods are poorly aligned and may not be suitable for forming bundles or films.

Aligned carbon nanotube films or bundles of aligned carbon nanotubes can be formed by aligning separately produced carbon nanotubes on a substrate surface and producing carbon nanotubes directly on a substrate. The latter method provides ease in achieving orientation in one direction and is a more advantageous method. Techniques for producing carbon nanotubes on a substrate include: (1) forming a catalytic metal membrane on a substrate, etching the membrane and thermally decomposing hydrocarbon on the substrate (U.S. Pat. No. 6,350,488); (2) preparing an iron-containing mesoporous silica substrate by a sol-gel method, reducing it with hydrogen and thermally decomposing acetylene on the substrate (Nature, 394, pp. 631-632 (1998)); (3) irradiating a substrate with plasma or microwaves to form carbon nanotubes (WO 99/043613); (4) forming a thin film of silicon carbide single crystal on a silicon substrate by epitaxial growth, separating it from the substrate by etching and heating it at high temperature in an oxygen-containing atmosphere (WO 98/042620); (5) anodizing an aluminum plate, electrodepositing cobalt on the bottom of the oxide film to prepare a substrate, reducing the substrate with carbon monoxide and thermally decomposing acetylene (U.S. Pat. No. 6,129,901); (6) forming a catalytic metal layer on a surface of a substrate by vacuum vapor deposition and thermally decomposing hydrocarbon (Japanese Laid-Open Publication No. 2001-220674); (7) preparing fine catalyst particles by a reverse micelle method or the like, loading them on a substrate and thermally decomposing hydrocarbon (Japanese Patent Laid-Open No. 2001-62299).

Another procedure for patterning silicon self-assembling monolayers with carbon nanotubes involves binding of antibody-carbon nanotubes to antigens linked in a desired pattern to the silicon self-assembling monolayers. Procedures for generating antibody-carbon nanotubes and attaching them to surfaces patterned with antigen molecules are described in Nuraje et al., JACS 126: 8088-8089 (2004). As described herein, antigens can be linked to silicon self-assembling monolayers by generating the desired pattern of reactive sites and then linking the antigen molecules to the reactive sites.

Protecting Groups

The term “protecting group” or “blocking group” refers to any group which when bound to one or more hydroxyl, thiol, amino, carboxylic acid, phosphate or carboxyl groups of the compounds (including intermediates thereof) prevents reactions from occurring at these groups and which protecting group can be removed by conventional chemical or enzymatic steps to reestablish the hydroxyl, thiol, amino, carboxylic acid, phosphate or carboxyl group. The particular removable blocking group employed is generally not critical and protecting groups available in the art can be used.

Examples of removable hydroxyl blocking groups include conventional substituents such as allyl, benzyl, acetyl, chloroacetyl, thiobenzyl, benzylidine, phenacyl, t-butyl-diphenylsilyl and any other group that can be introduced chemically onto a hydroxyl functionality and later selectively removed either by chemical or enzymatic methods in mild conditions compatible with the nature of the product. Preferred removable thiol blocking groups include disulfide groups, acyl groups, benzyl groups, and the like. Preferred removable amino blocking groups include conventional substituents such as t-butyoxycarbonyl (t-BOC), benzyloxycarbonyl (CBZ), fluorenylmethoxy-carbonyl (FMOC), allyloxycarbonyl (ALOC), and the like which can be removed by conventional conditions compatible with the nature of the product. Preferred carboxyl protecting groups include esters such as methyl, ethyl, propyl, t-butyl etc. which can be removed by mild conditions compatible with the nature of the product.

A number of protecting groups and procedures for their use are described in Protective Groups in Organic Synthesis, Theodora W. Greene (John Wiley & Sons, Inc., New York, 1991, ISBN 0-471-62301-6) (“Greene”). See also Kocienski, Philip J.; Protecting Groups (Georg Thieme Verlag Stuttgart, New York, 1994), which is incorporated by reference in its entirety herein.

The invention will be illustrated by the following non-limiting Examples.

### EXAMPLE 1

### Materials and Methods

This Example describes experiments performed to ascertain whether 2,2,6,6-tetramethyl-1-piperidinyloxy (TEMPO) could promote self-assembly of a monolayer on a Si(111)-H surface in the presence of an olefin. Si(111)-H was chosen because it can be easily formed in high yield, it is atomically flat, and it has few dangling reactive moieties.⁵ TEMPO is a stable free radical that is not reactive with most functional groups at room temperature. As illustrated below, monolayer assembly on Si(111)-H surfaces can be performed at room temperature using TEMPO and related sterically hindered free radical sources.

Materials

Distilled water, 1-octadecene (90%), hexane, 2,2,6,6-tetramethyl-1-piperidinyloxy (TEMPO, 98%), 4-hydroxy-2,2,6,6-tetramethylpiperidinyloxy, pentadecafluorooctanoyl chloride (97%), undecanoic acid (99%), oxalyl chloride (98%), Al₂O₃ (basic, Brockman activity 1), 2-hexyldecanoic acid, 4-dimethylamino)pyridine (99%), and 48% hydrofluoric acid were purchased from Acros or Aldrich and used as received. 40% NH₄F was purchased from J. T. Baker and used as received. All solvents were purchased from Acros and used as received.

Geduran silica gel 60 was purchased from Fisher and used for all purifications. Single-side polished Si(111) wafers (n-type) were purchased from Silicon Inc, Boise, Id.

TEMPO was sublimed under reduced atmosphere, dried under vacuum for 48 h, and stored in a −30° C. freezer in a glove box under N₂. 1-Octadecene was distilled with a Vigreux column under reduced pressure. Typically 500 mL were distilled at one time. The first 100 mL of distilled 1-octadecene was discarded. The next 300 mL of 1-octadecene was collected and transferred to a Kontes flask. The Kontes flask was evacuated under reduced pressure and back filled with N₂, this process was repeated three times. The Kontes flask was stored in the glove box.

¹H, ¹³C, and ¹⁹F NMR spectra were recorded on a Bruker DPX 300 using CDCl₃. The solvent signal was used as an internal standard. Trifluorotoluene (C₆H₅CF₃) was used as an internal standard for the ¹⁹F NMR.

Preparation of the Si(111)-H Surface and Assembly of the Monolayers

The steps for assembly of monolayers on the Si(111) shards were as follows. All monolayers were assembled for 24 hours at room temperature. The concentrations of TEMPO and the derivatives of TEMPO in 1-octadecene employed are outlined in Table 1. The 1-octadecene, TEMPO, and derivatives of TEMPO were stored in a glove box and all preparations involving these chemicals were performed inside of a glove box. Shards of Si(111) wafers were cut into sizes of approximately 1 cm by 2.5 cm. These shards were washed with hexanes, acetone, and methanol and then sonicated in acetone for 5 min. The shards were rinsed with water and treated with 5:1 (v/v) 40% NH₄F_{(aq)}/48% HF_{(aq)} for 30 sec to remove the native silicon dioxide layer. The samples were placed in 3:1 (v/v) of concentrated H₂SO₄/30%H₂O_{2(aq)} (piranha) for 1 h at 90° C. Piranha is exceedingly dangerous and should be kept from organic materials and treated with care. The wafers were removed from the piranha solution and washed with copious amounts of water. The wafers were hydrophilic after this treatment.

The 40% NH₄F was placed in a cup within a larger cup that was covered with a cap. The NH₄F was purged with Ar for 30 minutes to remove O₂ before the Si(111) shards were immersed. The larger cup was continuously purged with Ar while the Si(111) shards were immersed in the NH₄F for 20 min. The shards were removed and the NH₄F spontaneously dewetted from the surface. The shards were dried under a stream of N₂.

The shards were then immediately taken into the glove box and immersed in the solution of 1-octadecene with TEMPO or derivatives of TEMPO according to Table 1. The monolayers were assembled at room temperature in a sealed schlenk flask under N₂ for 24 h. After 24 h the shards were removed and washed with copious amounts of hexane, acetone, and methanol. Finally, the shards were sonicated twice for 3 min in CH₂Cl₂. New CH₂Cl₂ was used for each sonication.

The contact angles were immediately measured on their surfaces. For entries 14 and 15 in Table 1 the monolayers were assembled in neat hexane. Hexane was added to a Kontes flask and taken through four freeze-pump-thaw cycles. The hexane was transferred into the glove box and passed over Al₂O₃ that was activated in a 125° C. oven overnight. The hexane was collected and stored in a Kontes flask until use.

Contact Angle Goniometry.

Contact angles were measured on a Ramé-Hart model 100 goniometer at room temperature and ambient humidity. An Eppendorf EDOS 5222 was used to dispense distilled water. Small drops of water (5 μL) were dispensed at a time and the contact angles were measured immediately. A minimum of 15 measurements at two different spots on the surface were collected for each sample. The error in the measurements of the advancing contact angles were typically small; for contact angles of greater than 100° most of the measurements came within ±1 of the reported value. Contact angles less than 100° had errors of ±2.

X-ray Photoelectron Spectroscopy (XPS)

XPS was performed at the University of Illinois at the Center for Microanalysis of Materials (CMM). The instrument was a Kratos axis ultra X-Ray photoelectron spectrometer. The image area was 300 by 700 μm and the take-off angle was 90°. The pass energy on the survey scan (0 to 1100 eV) was 160 eV. High resolution scans of the Si(2p) (92 to 108 eV binding energy), C(1s) (274 to 300 eV binding energy), O(1s) (523 to 539 eV binding energy), and F(1s) (680 to 696 eV binding energy) were performed. The atomic compositions reported in Table 1 were corrected for the atomic sensitivities and measured from the high resolution scans. The atomic sensitivities were 1.000 for F(1s), 0.780 for O(1s), 0.278 for C(1s), and 0.328 for Si(2p).

Stability of the Monolayers to Air and Boiling Chloroform.

The silicon shards with monolayers as assembled in entries 2 and 3 in Table 1 were split in half. One half of the shards were stored in a glove box under N₂ until they were studied by XPS as reported in Table 1. The other half was stored in closed vials under an atmosphere of air for 48 days, immersed in boiling chloroform for 1 hour in air, and washed with hexanes, acetone, and methanol. These shards were then studied by XPS. The XPS spectra of the samples that were exposed to air and those kept in a glove box were identical.
Synthesis of TEMPO-F₁₅.

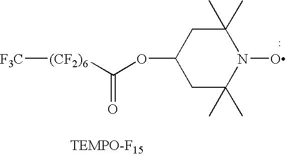

4-Hydroxy-2,2,6,6-tetramethylpiperidinyloxy (1.33 g, 7.7 mmol) was added to a schlenk flask. The flask was evacuated under reduced pressure and backfilled with N₂ three times. Methylene chloride (40 mL) and 4-(dimethylamino)pyridine (1.41 g, 11.55 mmol) were added to the flask under positive N₂ pressure. Pentadecafluorooctanoyl chloride (4.0 g, 9.3 mmol) was added and the reaction was stirred for 10 h. The reaction was extracted with 50 mL H₂O/10 mL concentrated HCl twice and with 50 mL H₂O twice. The product was rotovapped to a red solid. The product was cleaned by column chromatography in 5% ethyl acetate/hexanes. A red solid was isolated (3.00 g, 68% yield), evacuated under reduced pressure for 24 h, and stored in a −30° C. freezer in a glove box. Phenyl hydrazine was added to the NMR tube. ¹H NMR (CDCl₃): δ 1.12 (s, 3H), 1.13 (s, 3H), 1.61 (t, J=11.4 Hz, 2H), 1.89 (m, 2H), 5.18 (t of t, J=11.4 Hz and 4.5 Hz, 1H). ₁₉F NMR (CDCl₃ with C₆H₅CF₃): δ-80.36 (t of t, J=2.7 Hz and 10.5 Hz, 3F), −118.15 (t of t, J=2.7 Hz and 13.2 Hz, 2F), −121.22 (m, 2F), −121.63 (m, 2F), −122.01 (m, 2F), −122.33 (m, 2F), −125.68 (m, 2F). HRMS: Calculated for C₁₇H₁₇NO₃F₁₅: 568.0969. Found: 568.0969.
Synthesis of TEMPO-C₁₀.

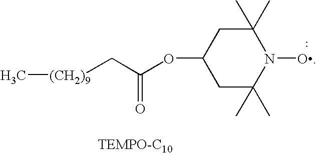

Undecanoic acid (3.24 g, 17.4 mmol) was added to a schlenk flask. The flask was evacuated under vacuum and backfilled with N₂ three times. Methylene chloride (30 ml) was added to the flask under positive N₂ pressure. The flask was cooled in an ice bath for 15 min. Oxalyl chloride (6.64 g, 52.3 mmol) was added to the flask. The flask was removed from the ice bath and warmed to room temperature. After 5 h the reaction mixture was rotovapped to remove the methylene chloride and excess oxalyl chloride. 4-Hydroxy-2,2,6,6-tetramethylpiperdinoxy (2.5 g, 14.5 mmol), pyridine (2.3 g, 27.5 mmol), and methylene chloride (30 ml) were added to a schlenk flask under positive N₂ pressure and cooled in an ice bath. The acid chloride was added, and the reaction was allowed to stir at room temperature for 18.5 h. The reaction was extracted with 40 mL water five times. The organic layer was collected and the solvent was removed by reduced pressure to give a red crystalline product. The product was then purified by column chromatography in 8% ethyl acetate/hexanes. A red solid (3.85 g, 78.1% yield) resulted. Phenyl hydrazine was added to the NMR tube. ¹H NMR (CDCl₃): δ: 0.75 (t, J=7.5 Hz, 3H), 0.98-1.28 (m, 26H), 1.52 (m, 4H), 1.82 (m, 2H), 2.20 (t, J=12.0 Hz, 2H), 5.00 (t of t, J=12.0 Hz and 4.5 Hz, 1H). ¹³C NMR δ: 13.96, 20.37, 22.51, 24.81, 28.94, 29.10, 29.14, 29.30, 29.39, 31.74, 34.39, 43.75, 59.16, 66.29, 173.22. HRMS: Calculated for C₂₀H₃₈NO₃: 340.2852. Found: 340.2859.
Synthesis of TEMPO-C₆C₈.

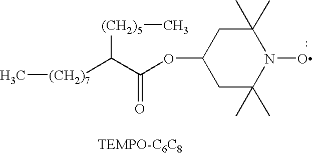

2-Hexyldecanoic acid (1.95 g, 10.45 mmol) was added to a schlenk flask. The flask was evacuated under vacuum and backfilled with N₂ three times. Methylene chloride (30 ml) was added to the flask under positive N₂ pressure. The flask was cooled in an ice bath for 15 min. Oxalyl chloride (3.98 g, 31.4 mmol) was added to the flask. The flask was removed from the ice bath and warmed to room temperature. After 9 h the reaction mixture was rotovapped to remove the methylene chloride and excess oxalyl chloride. 4-Hydroxy-2,2,6,6-tetramethylpiperdinooxy (1.5 g, 8.71 mmol), pyridine (1.38 g, 17.4 mmol), and methylene chloride (25 ml) were added to a schlenk flask under positive N₂ pressure and cooled in an ice bath. The acid chloride was added, and the reaction was allowed to stir at room temperature for 9 h. The reaction was extracted with 20 mL water five times. The organic layer was collected and the solvent was removed by reduced pressure to give a red crystalline product. The product was then purified by column chromatography in 8% ethyl acetate/hexanes. A red liquid (2.68 g, 74.5% yield) was recovered. Phenyl hydrazine was added to the NMR tube. ¹H NMR (CDCl₃): δ: 0.77 (t, J=7.5 Hz, 6H), 1.05-1.25 (m, 32H), 1.25-1.38 (m, 2H), 1.38-1.72 (m, 4H), 1.82 (m, 2H), 2.16 (m, 1H), 5.00 (t of t, J=12.0 Hz and 4.5 Hz, 1H). ¹³C NMR δ: 14.06, 14.10, 20.54, 22.56, 22.65, 27.34, 27.37, 29.16, 29.21, 29.40, 29.50, 31.65, 31.83, 31.99, 32.50, 44.08, 45.80, 59.00, 66.28, 176.16. HRMS: Calculated for C₂₅H₄₈NO₃: 410.3634. Found: 410.3633.

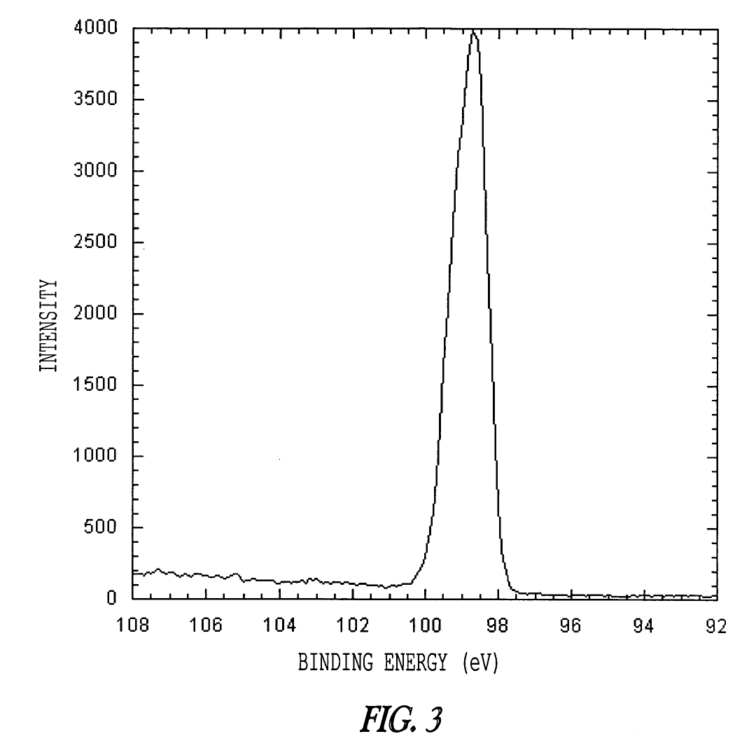

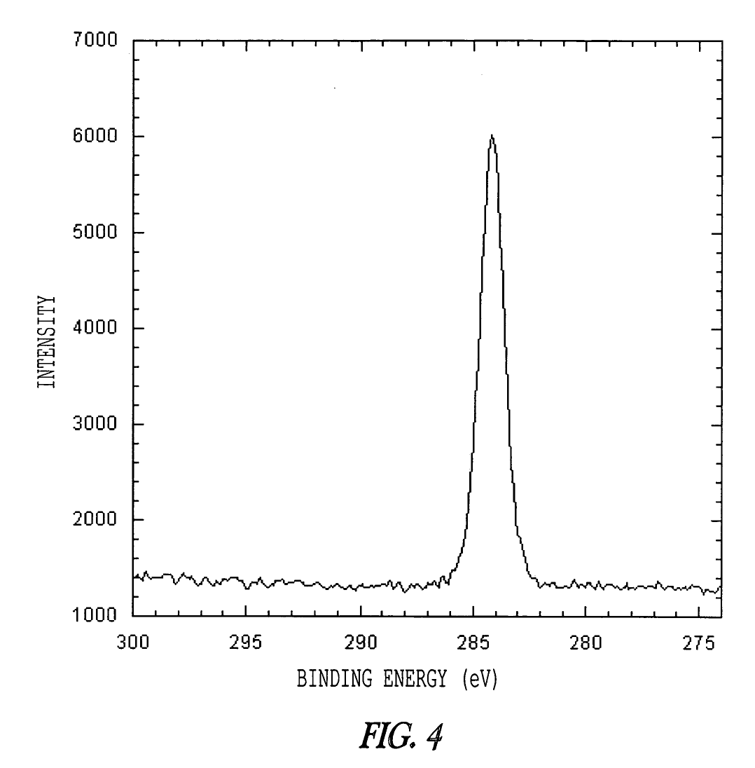

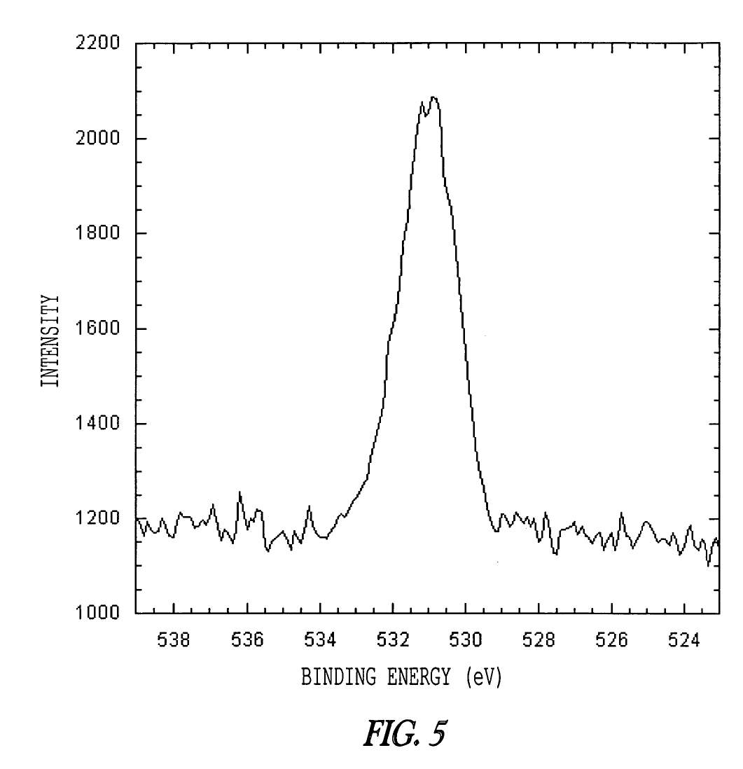

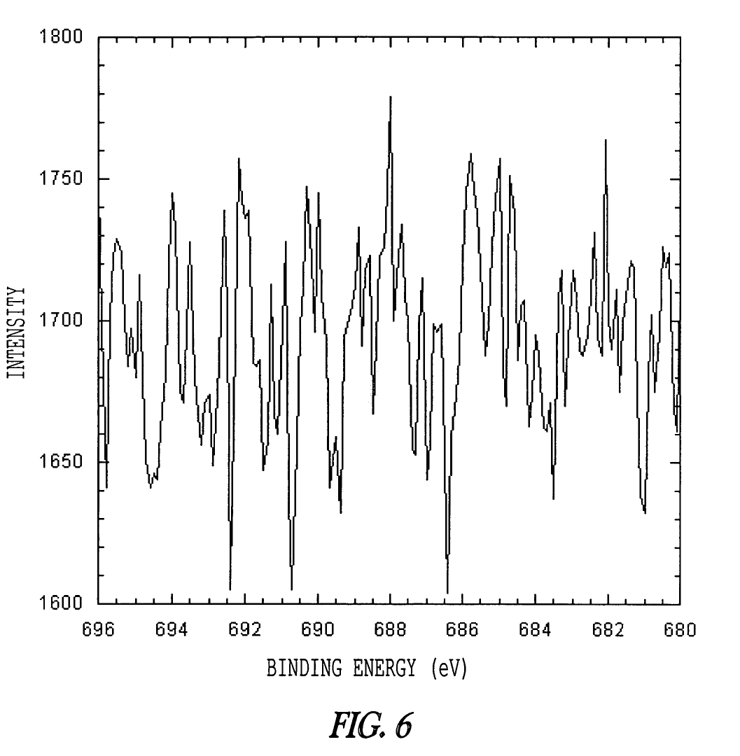

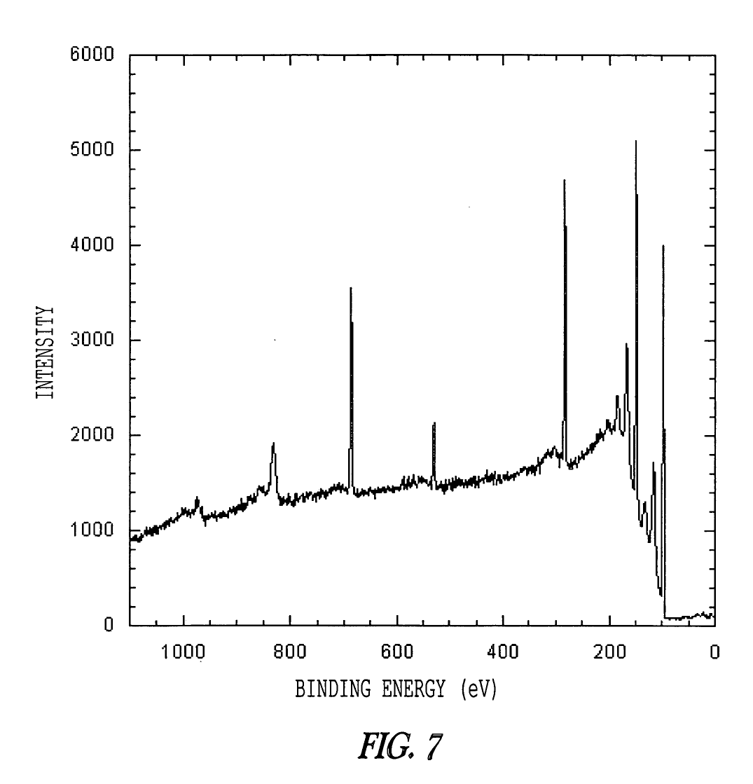

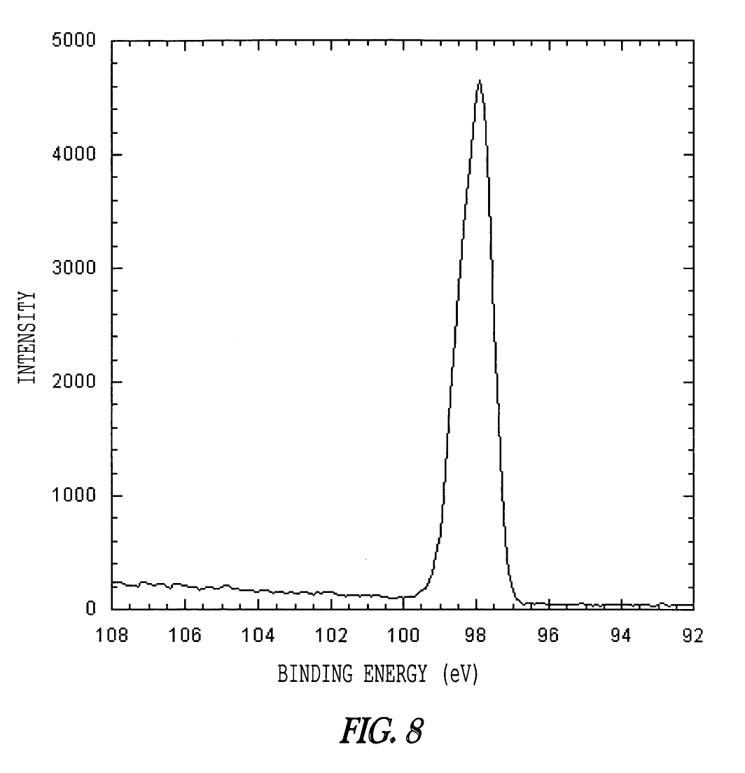

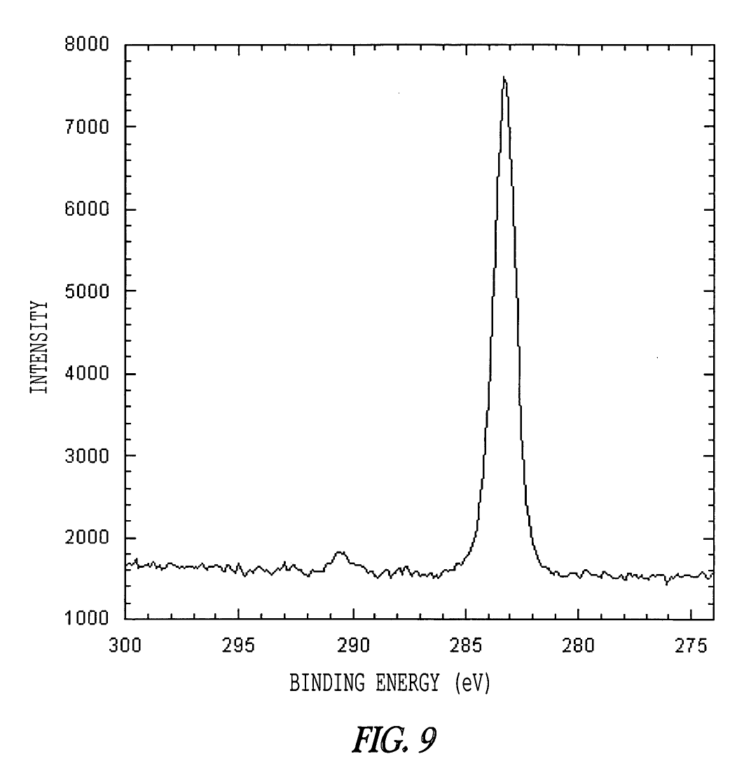

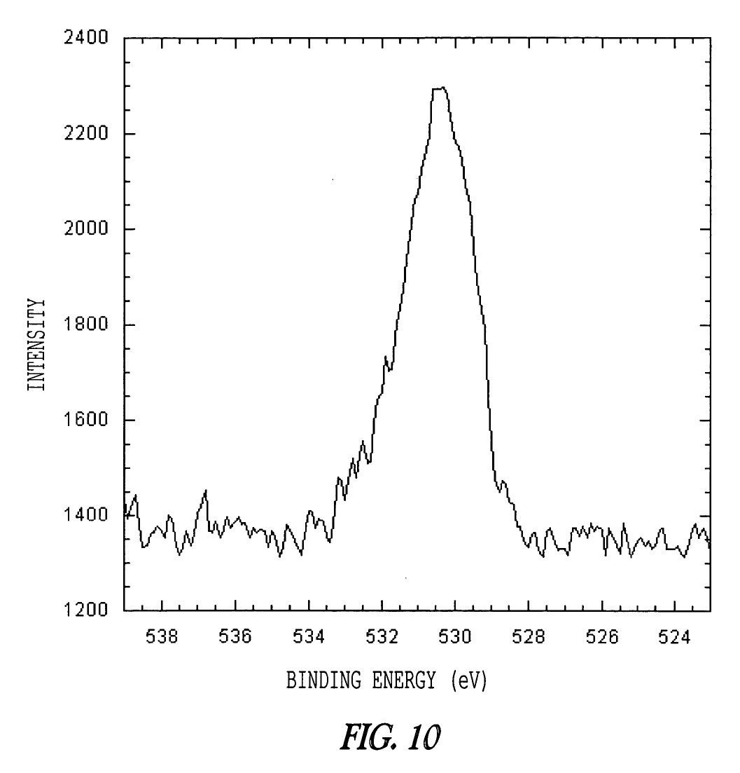

Representative examples of the XPS spectra summarized in Table 1 are provided in FIGS. 2-11.

### EXAMPLE 2

### Monolayer Assembly on Si(111)-H Surfaces Proceeds Under Mild Conditions in the Presence of TEMPO

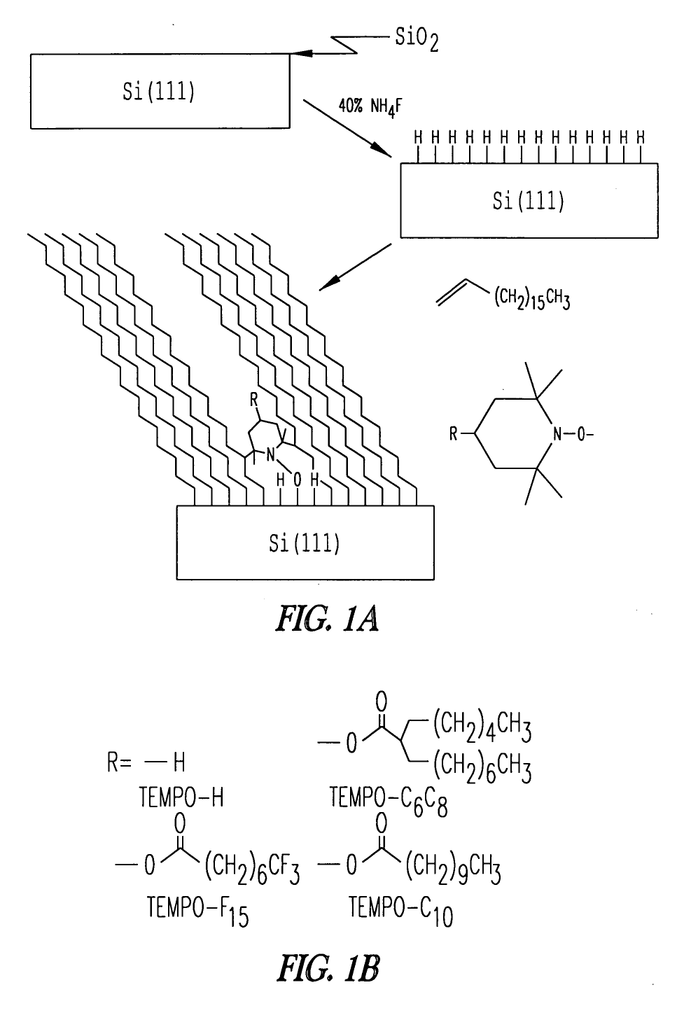

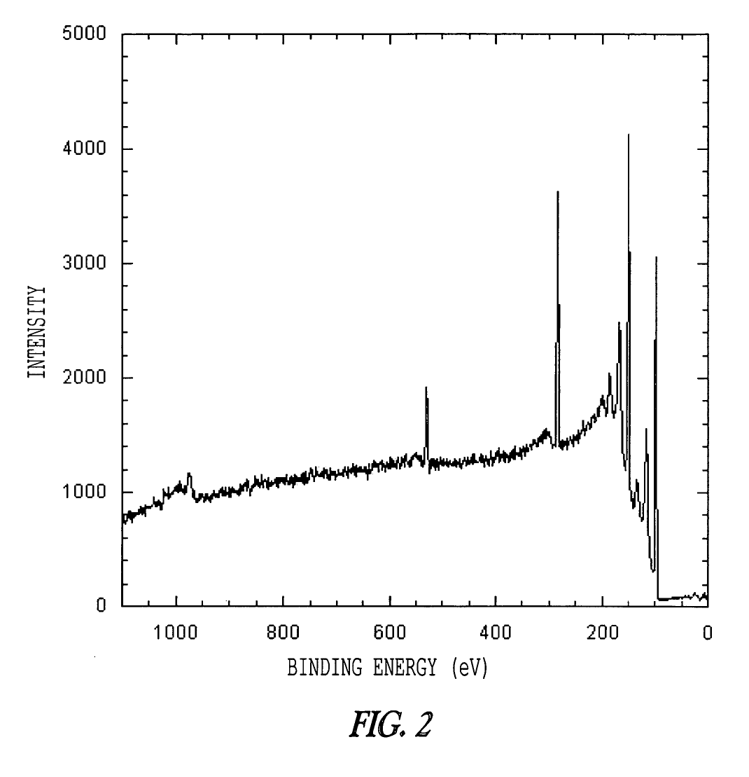

The reaction of TEMPO and 1-octadecene with Si(111)-H was performed at room temperature as illustrated schematically in FIG. 1, and as described in detail in Example 1. Briefly, silicon wafers were cleaned in organic solvents and the native silicon dioxide layer was removed with 5:1 40% NH₄F/48% HF at. A thin layer of silicon dioxide on the wafer was generated by placing the wafer in 1:3 30% H₂O₂/concentrated sulfuric acid at 90° C. for 1 hour. Si(111)-H was formed on the wafer surface by immersion of the wafer in 40% NH₄F under an atmosphere of argon using procedures generally outlined in Wade et al. APPL. PHYS. LETT. 71: 1679-81 (1997) and Higashi et al. APPL. PHYS. LETT 56: 656-658 (1990). The silicon wafer was then placed in a schlenk flask of TEMPO and 1-octadecene in a glove box under N₂. The formation of the monolayer was initially monitored by following the advancing contact angle of water on the silicon surfaces as a function of time immersed in TEMPO and 1-octadecene. At times of less than 3 hours, the advancing contact angles of water were less than 100°, thus all further reactions were run for 24 h at room temperature.

The contact angles of water for monolayers assembled using various concentrations of TEMPO in neat 1-octadecene were studied (see Table 1, entries 1 to 5). The best contact angle of 110° was measured on monolayers assembled from 1.0 to 0.1 mole percent TEMPO. These values for advancing contact angles of water can be compared to values reported by others for monolayers of alkanes on Si(111) or Si(100) of 104°, 105°-109°, 109°, 111°-113°, and 110°. In addition disordered monolayers of alkanes and polymethylene surfaces yielded contact angles of 102° (entry 16 in Table 1) to 103° (see Linford et al., J. AM. CHEM. SOC. 117:3145-55 (1995); Holmes-Farley et al., LANGMUIR 1:725-40 (1985)). Thus, well-ordered monolayers of alkanes that expose a methyl group on the surface have contact angles of 110° or higher and disordered monolayers that expose methylene groups have measurably lower contact angles. The results provided herein indicate that well-ordered monolayers were formed.

TABLE 1
The contact angles and atomic compositions from XPS for
various monolayers assembled on Si(111).

| | | ^{a}TEMPO-R | | | | ^{b}H₂O Contact | | ^{c}XPS Atomic | | | | |
|---|---|---|---|---|---|---|---|---|---|---|---|---|
| | | (mole %) | | | | Angle (°) | | Composition (%) | | | | |
| Entry | ^{d}Olefin | H | F₁₅ | C₁₀ | C₆C₈ | A | R | SiO₂ | Si | F | C | O |
| 1 | C₁₈H₃₆ | 10 | | | | 106 | 104 | 0 | 43 | 0 | 52 | 6 |
| 2 | C₁₈H₃₆ | 1.0 | | | | 110 | 107 | 0 | 39 | 0 | 54 | 7 |
| 3 | C₁₈H₃₆ | 0.1 | | | | 110 | 107 | 0 | 36 | 0 | 59 | 5 |
| 4 | C₁₈H₃₆ | 0.01 | | | | 108 | 107 | 0 | 32 | 0 | 62 | 6 |
| 5 | C₁₈H₃₆ | 0.001 | | | | 106 | 103 | 0 | 34 | 0 | 59 | 7 |
| 6 | C₁₈H₃₆ | | 1 | | | 114 | 113 | 0 | 31 | 18 | 46 | 4 |
| 7 | C₁₈H₃₆ | | 0.1 | | | 112 | 111 | 0 | 31 | 6 | 58 | 4 |
| 8 | C₁₈H₃₆ | | 0.01 | | | 111 | 110 | 0 | 30 | 7 | 59 | 4 |
| 9 | C₁₈H₃₆ | | 0.001 | | | 110 | 108 | 0 | 33 | 6 | 55 | 5 |
| 10 | C₁₈H₃₆ | | | 1.0 | | 112 | 107 | 0 | 35 | 0 | 60 | 5 |
| 11 | C₁₈H₃₆ | | | 0.1 | | 111 | 105 | 0 | 33 | 0 | 60 | 7 |
| 12 | C₁₈H₃₆ | | | | 1.0 | 111 | 107 | 0 | 34 | 0 | 61 | 6 |
| 13 | C₁₈H₃₆ | | | | 0.1 | 111 | 106 | 0 | 33 | 0 | 61 | 6 |
| ^{e}14 | None | 0.1 | | | | 85 | 71 | 5 | 29 | 0 | 18 | 48 |
| ^{e}15 | None | | 0.1 | | | 89 | 78 | 2 | 36 | 8 | 24 | 29 |
| ^{f}16 | C₁₈H₃₆ | | | | | 102 | 91 | Trace | 37 | 0 | 51 | 12 |

^{a}These values are the mole percent of TEMPO-R in the 1-octadecene. Values that are blank have a concentration of zero.
^{b}The errors in the advancing (A) and receding (R) contact angles were approximately ±1.
^{c}The Si(2p), F(1s), C(1s), and O(1s) peaks were studied. The peak corresponding to SiO₂ appeared at approximately 102 eV in the Si(2p) high resolution scan.
^{d}The olefin was 1-octadecene.
^{e}The TEMPO and TEMPO-F₁₅ in these entries were at the same concentrations as TEMPO in entry 3. The monolayers were assembled in hexane.
^{f}No TEMPO or derivatives of TEMPO were used to assemble this monolayer.

Experiments were then performed to ascertain whether the presence of TEMPO would disorder the top of the monolayer and expose methylene groups because TEMPO is shorter than the alkene (FIG. 1). Three derivatives of TEMPO were synthesized to increase its steric requirements as described above in Example 1. Monolayers assembled from 1-octadecene and TEMPO-C₁₀ or TEMPO-C₆C₈ had advancing contact angles of water from 111° to 112°, monolayers assembled from 1-octadecne and TEMPO-F₁₅ had advancing angles of water from 110° to 114° (entries 6 to 13 in Table 1). These are some of the highest contact angles observed for monolayers of alkanes on Si(111) and indicate that additional steric bulk on derivatives of TEMPO results in monolayers that are more ordered than those assembled from TEMPO.

Other workers have shown that well-ordered monolayers on silicon prevent the oxidation of silicon to silicon dioxide, and disordered monolayers do not prevent this oxidation.^{2,4} The absence of oxidized silicon is further proof that the monolayers generated by the methods of the invention are well-ordered. In Table 1, monolayers assembled from 1-octadecene with TEMPO or derivatives of TEMPO showed no evidence of silicon dioxide from the Si(2p) peak in the x-ray photoelectron spectroscopy (XPS). In contrast, disordered monolayers from the assembly of TEMPO or TEMPO-F₁₅ in hexane and from neat 1-octadecene without TEMPO had peaks in the XPS that correspond to oxidized silicon (entries 14 to 16 in Table 1).

To further analyze the quality of the monolayers, the stability of monolayers from entries 2 and 3 in Table 1 were analyzed. These monolayers were exposed to air for 48 days and boiled in chloroform for one hour. The XPS spectra showed no evidence for silicon dioxide on these monolayers.

However, the XPS spectra exhibited a peak for oxygen that could arise from oxidized silicon or TEMPO. TEMPO-F₁₅ was synthesized to provide a clear handle in the XPS to determine whether TEMPO-F₁₅ was bonded to the surface. The presence of fluorine in the XPS indicates that TEMPO-F₁₅ bonds with the silicon hydride surface at measurable amounts. Thicknesses of these monolayers was not known and a more detailed analysis of their XPS spectra was not possible. Thus, it appears that alt least some of the oxygen in the XPS spectra can be assigned to TEMPO.

Three lines of evidence indicate that the monolayers generated by the methods of the invention were well-ordered. First, the advancing contact angles of water are among the highest reported for ordered monolayers on silicon. Second, XPS spectra of the monolayers do not show evidence of the presence of silicon dioxide based on the absence of a peak corresponding to SiO₂ in the Si(2p) region. Third, the monolayers protect the silicon surface from oxidation at extended time periods and under boiling chloroform. The exact mechanism by which TEMPO facilitates organized monolayer formation is not known but either TEMPO or derivatives and related molecules are necessary to form an ordered monolayer.

### EXAMPLE 3

### Cross Metathesis on Olefin-Terminated Monolayers on Si(111) Using Grubbs' Catalyst

This Example describes the functionalization and patterning of olefin-terminated monolayers on Si(111) through cross metathesis. A simple, one-step synthesis of a diolefin —CH₂═CH(CH₂)₉O(CH₂)₉CH═CH₂—was developed from commercially available starting materials. Mixed partially olefin-terminated monolayers of this novel diolefin and 1-octadecene on hydrogen-terminated Si(111) were obtained. The olefins are raised above the rest of the monolayer and thus sterically accessible for further functionalization. Olefin-terminated monolayers were reacted with the Grubbs' first generation catalyst and olefins in solution that were terminated with fluorines, carboxylic acids, alcohols, aldehydes, and alkyl bromides. Characterization of these monolayers using x-ray photoelectron spectroscopy and horizontal attenuated total reflection infrared spectroscopy demonstrated that olefins on the surface had reacted via cross metathesis to expose fluorines, carboxylic acids, aldehydes, alcohols, and bromides. Calibration experiments were used to demonstrate a simple 1:1 correspondence between the ratio of olefins in solution used in the assembly and the final composition of the mixed monolayers. Finally, these monolayers on silicon were patterned on the micrometer-size scale by soft lithography using microfluidic channels patterned into PDMS stamps. Micrometer-wide lines of polymer brushes were synthesized on these monolayers and characterized by scanning electron microscopy. In addition, olefin-terminated monolayers were patterned into micrometer-sized lines exposing carboxylic acids by cross metathesis with olefins in solution. This method of patterning is broadly applicable and can find applications in a variety of fields including the development of biosensors and nanoelectronics.

Materials and Methods. 1-Octadecene (90%), 10-undecenoic acid (98%), 10-undecen-1-ol (99%), 10-undecenal (97%), 11-bromo-1-undecene (95%), 1,6-dichlorohexane (95%), 1-undecanol (98%), potassium tert-butoxide, 5-norbornene-2-carboxylic acid (98%), and 48% hydrofluoric acid were purchased from Acros or Aldrich and used as received. 40% NH₄F was purchased from J. T. Baker and used as received. All solvents were purchased from Acros and used as received. Single-side polished Si(111) wafers (n-type) were purchased from Silicon Inc, Boise, Idaho. Grubbs' catalyst first generation is benzylidene-bis(tricyclohexylphosphine)dichlororuthenium and is available from Sigma-Aldrich.

TEMPO-C₁₀ was synthesized as described in Example 1. It was stored in a −30° C. freezer in a glove box under N₂. 1-Octadecene and 10-undecenoic acid were distilled with a Vigreux column under reduced pressure. Typically, 500 mL were distilled and the middle third of the fractional distillation was used. The collected fraction was transferred to a Kontes flask. The Kontes flask was evacuated under reduced pressure for 48 h and back filled with N₂, this process was repeated three times. The Kontes flask was stored in the glove box.

Instrumentation: ¹H and ¹³C were recorded on a Bruker DPX 300 using CDCl₃. The solvent signal was used as internal standard.

X-ray Photoelectron Spectroscopy (XPS). X-ray photoelectron spectra were obtained on a Kartos Axis Ultra Imaging spectrometer. Spectra of C(1s) (275-295 eV binding energy), O(1s) (525-545 eV binding energy), F(1s) (675-695 eV binding energy), Si(2p) (90-110 eV binding energy), Cl(2p) (190-210 eV binding energy), and Br(3d) (60-70 eV binding energy) as well as survey scans (0-1100 eV) were recorded with a tilt angle of 45°. The atomic compositions were corrected for atomic sensitivities and measured from high-resolution scans. The atomic sensitivities were 1.000 for F(1s), 0.780 for O(1s), 0.278 for C(1s), 0.328 for Si(2p), 0.891 for Cl(2p), and 1.055 for Br(3d).

Horizontal Attenuated Total Reflectance Infrared Spectroscopy. These spectra were recorded using a Bruker Tensor 27 equipped with an MCT detector cooled with liquid nitrogen. Monolayers were assembled on Si(111) HATR crystals with dimensions of 80×10×5 mm. The crystals were mounted in a dry air purged sample chamber. Background spectra were performed using freshly oxidized surfaces of HATR crystals. Scans were measured at a resolution of 4.0 cm⁻¹ or 2.0 cm⁻¹.

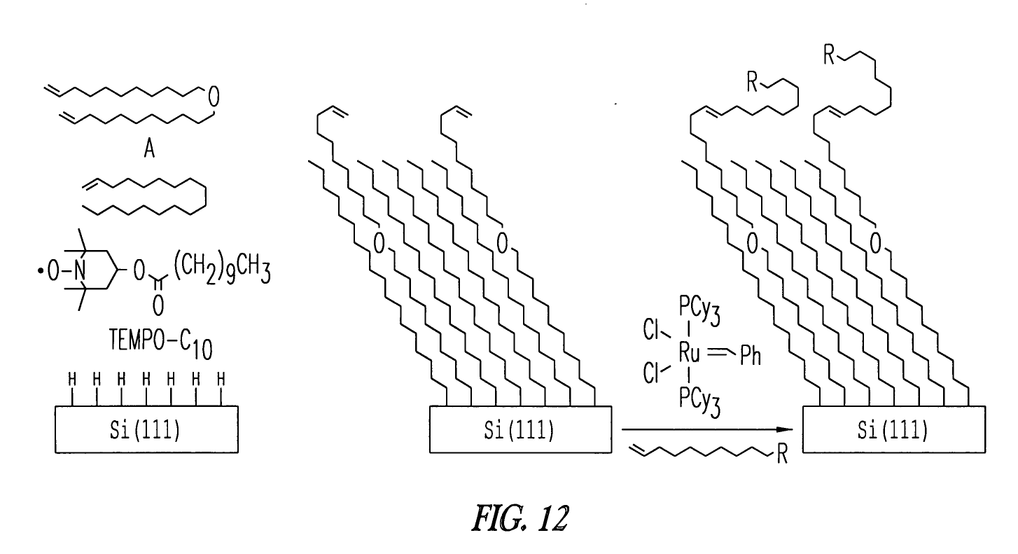

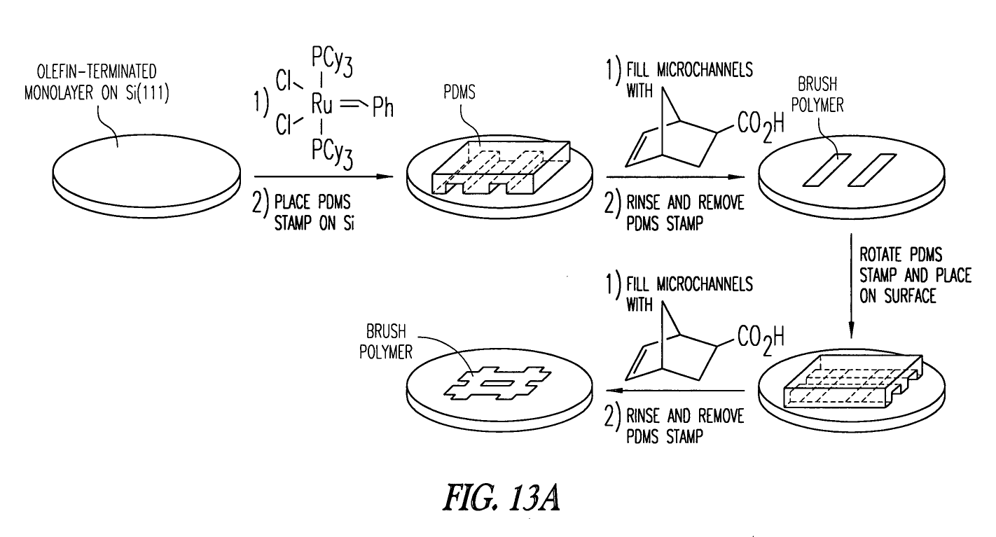

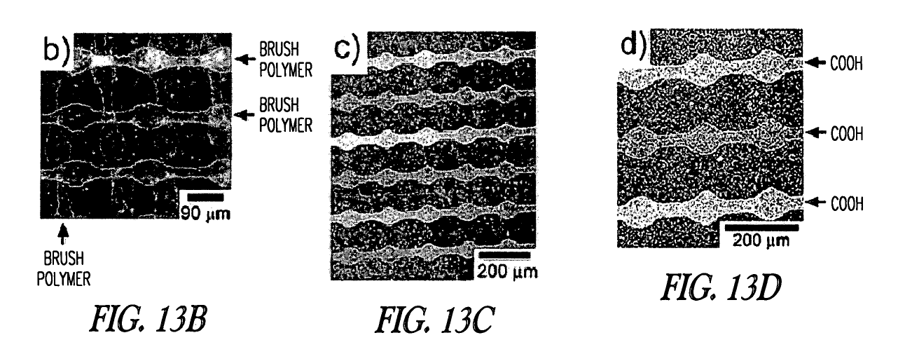

Scanning Electron Microscopy. Si(111) shards that were patterned as shown in FIG. 13 were examined with a Hitachi S-4000 Scanning Electron Microscope. Typically, an accelerating voltage of 5 kV was used to image the patterns on the surface.

Synthesis of 11,11′-Oxybis-1-undecene (A). 10-Undecen-1-ol (60 g, 0.352 mol), triethyl amine (28.4 g, 0.281 mol), and p-tolulenesulfonyl chloride (26.8 g, 0.140 mol) were stirred under nitrogen at room temperature for 24 h in 360 mL of THF. Potassium tert-butoxide (39.4 g, 0.352 mol) was added to the reaction mixture and stirred for 7 h. The solvent was evaporated and the product was extracted with methylene chloride. After evaporation the product was distilled as a colorless oil under vacuum at 200° C. and stored in a −30° C. freezer in a glove box. Yield: 61%. ¹H NMR (300 MHz, CDCl₃, ppm): δ5.82 (2H, m), 4.96 (4H, m), 3.38 (4H, t, J=6.9 Hz), 2.02 (4H, q, J=6 Hz), 1.54 (4H, m), 1.28 (24H, m). ¹³C NMR (300 MHz, CDCl₃, ppm): 138.9, 114.0, 70.8, 33.7, 29.7, 29.4 (3 peaks), 29.0, 28.8, 26.1.

Synthesis of CH₂═CH(CH₂)₉O(CH₂)₁₀CH₃. In a round bottom flask, 1-undecanol (58.3 g, 0.154 mol) and potassium tert-butoxide (38.0 g, 0.339 mol) were added under nitrogen to 250 mL of THF. The solution turned yellow and cloudy. 11-Bromo-1-undecene (35.9 g, 0.154 mol) was added and the mixture was refluxed under nitrogen. The product was isolated as a clear liquid by distillation under vacuum at 200° C. and stored in a −30° C. freezer in a glove box. Yield: 44%. ¹H NMR (300 MHz, CDCl₃, ppm): δ5.76 (1H, m), 4.92 (2H, m), 3.36 (4H, t, J=6 Hz), 1.99 (2H, m), 1.52-1.25 (32H, m), 0.85 (3H, t, J=6 Hz). ¹³C NMR (300 MHz, CDCl₃, ppm): δ 139.2, 114.0, 70.9, 33.8, 31.9, 29.8, 29.6, 29.5, 29.4 (4 peaks), 29.3, 29.1, 28.9, 26.2, 22.7, 14.1.

Synthesis of CH₂═CH(CH₂)₉O(CH₂)₆Cl. In a round bottom flask, 10-undecen-1-ol (26.5 g, 0.156 mol) and potassium tert-butoxide (20.9 g, 0.339 mol) were added under nitrogen to 450 mL of THF. 1,6-Dichlorohexane (72.4 g, 0.467 mol) was added and the mixture was refluxed under nitrogen. The solvent was removed by evaporation and the product was extracted with methylene chloride from water. The product was purified by column chromatography with 3% ethyl acetate/97% hexane. Yield: 22%. ¹H NMR (300 MHz, CDCl₃, ppm): δ 5.79 (1H, m), 4.94 (2H, m), 3.46 (2H, t, J=6 Hz), 3.34 (4H, m), 1.97 (2H, m), 1.71 (2H, m), 1.52-1.33 (20H, m). ¹³C NMR (300 MHz, CDCl₃, ppm): δ 138.8, 113.9, 70.7, 70.4, 44.7, 33.6, 32.4, 29.6, 29.3 (4 peaks), 28.9, 28.7, 26.5, 26.0, 25.3.

Assembly of Mixed Monolayers of 11,11′-Oxybis-1-undecene and 1-Octadecene. Silicon(111) shards cleaned with a nitrogen gun and rinsed with hexane, acetone, and methanol. The wafers were etched in 1:5 (v/v) of 48% HF/40% NH₄F solution for 30 sec. The wafers were oxidized with 1:3 v/v of H₂O₂:H₂SO₄ for 1 h at 90° C. (Caution: Pirhana solution is highly dangerous and should be handled with care.) The oxidized wafers were washed with water. The wafers were then etched with 40% NH₄F for 30 min under an atmosphere of argon. This process yielded hydrogen-terminated silicon(111). The wafer was dried with a nitrogen gun and immediately transferred to a glove box.

The shards were immersed in solution of 11,11′-oxybis-1-undecene and 1-octadecene with 0.1 mole % of TEMPO-C₁₀ in the glove box. Typically, a mixed monolayer with a 1:1 mole ratio of 11,11′-oxybis-1-undecene/1-octadecene was assembled on the hydrogen-terminated Si(111) shards by mixing 11,11′-oxybis-1-undecene (3 mL, 2.3 g, 7.0 mmol) and 1-octadecene (2.34 mL, 1.84 g, 7.0 mmol) with 0.1 mole % of TEMPO-C₁₀ (0.005 g, 0.007 mmol). The wafer was sealed in a Schlenk flask under nitrogen for 24 h. After 24 h, the shards were washed with various solvents and sonicated with CH₂Cl₂.

Representative Procedure for Cross-Metathesis on Mixed Monolayers. A Si(111) shard with an olefin-terminated monolayer, Grubbs' first generation catalyst (0.054 g, 0.06 mmol), CH₂Cl₂ (3 mL), and 10-undecenoic acid (1 mL, 5.4 mmol) were added to a round bottom flask in a glove box. The flask was fitted with a reflux condenser and removed from the glovebox and attached to a nitrogen line. The reaction was refluxed under nitrogen for 48 h. The wafer was taken out and washed with hexanes, acetone and methanol. The yield of the cross-metathesis reaction was determined by ¹H NMR. These conditions always gave a yield of 100%. ¹H NMR (300 MHz, CDCl₃, ppm): δ 5.36 (2H, br), 2.34 (4H, t, J=6 Hz), 1.98 (4H, m), 1.60 (4H, m), 1.29 (20H, br).

Patterning Brush Polymers using Soft Lithography. Typically, an olefin-terminated monolayer on a Si(111) shard was treated with a solution of Grubbs' first generation catalyst in methylene chloride for 30 min under ambient conditions. Next, the wafer was washed with methylene chloride and dried with nitrogen. A polydimethylsiloxane (PDMS) stamp patterned in bas-relief was then pressed onto the surface and a solution of 5-norbornene-2-carboxylic acid (0.01 g mL⁻¹) in DMF was passed through the microchannels with a syringe pump for 1 h at the rate of 200 μL h⁻¹. The channels were then flushed with DMF for 1 h. The PDMS stamp was then removed, rotated at an angle and the process was repeated. The wafer was washed with copious amounts of organic solvents and dried with nitrogen.

Results

Assembly of Mixed Monolayers of 1-Octadecene and a Diolefin. A simple, one pot synthesis of A from commercially available starting materials was developed and is shown below. 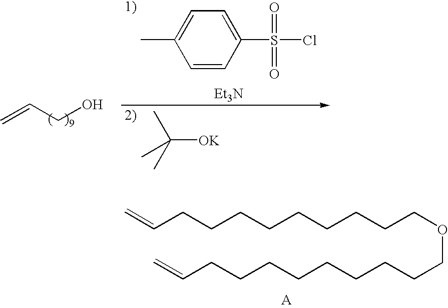
This method was used to synthesize up to 56 grams of A that was readily cleaned by distillation. The full synthesis of A is described above.

Characterization of Monolayers of 1-Octadecene and A. The method employed to assemble monolayers on Si(111) is shown in FIG. 12. Hydrogen-terminated Si(111) is air and water sensitive as it will readily oxidize to form a thin layer of silicon dioxide on the surface; however, well-ordered monolayers on Si(111) protect the surface from oxidation in air and solvents for days to months. The method used to form hydrogen-terminated Si(111) was similar to that developed by Burrows et al. Appl. Phys. Lett. 53: 998-1000 (1988); Wade et al. Appl. Phys. Lett. 71: 1670-81 (1997); Higashi et al. Appl. Phys. Lett. 56: 656-658 (1990). The silicon wafer was then placed in mixtures of 1-octadecene, A, and TEMPO-C₁₀.

The hydrogen-terminated Si(111) was characterized by horizontal attenuated total reflection infrared (HATR-IR) spectroscopy. The Si(111)-H bonds are perpendicular to the surface and only IR-active with p-polarized light and are not seen with s-polarized light. Higashi et al. reported that the Si(111)-H peak appears at 2083.7 cm⁻¹ with a narrow FWHM of 0.95 cm⁻¹ (Higashi et al. Appl. Phys. Lett. 56: 656-658 (1990)). The hydrogen-terminated Si(111) surfaces prepared as described herein were well-ordered—one peak with p-polarized light at 2084 cm⁻¹ was observed with a FWHM of 3.8 cm⁻¹ and no peaks with s-polarized light. These results demonstrated that a well-ordered hydrogen-terminated Si(111) surface was formed.

In addition to HATR-IR spectroscopy, the monolayers were characterized by XPS. Previous work on the assembly of monolayers of 1-octadecene with TEMPO (described above) showed that several important characteristics of these monolayers that are important for the interpretation of the characterization of the monolayers reported. First, this method results in the assembly of a monolayer with a thickness given by ellipsometry of approximately 1.8 nm. Second, the monolayer is almost entirely composed of 1-octadecene with less than 1 mole % of TEMPO on the surface. Third, although TEMPO is necessary for the assembly of a well-ordered monolayer, the mechanism of assembly and the role of TEMPO and not known with certainty.

Table 2 provides information about the XPS spectra of monolayers assembled from A. This surface was first characterized by a survey scan that showed the presence of Si, C, and O and high resolution scans of Si, C, O, and F. The region for F was examined as hydrogen-terminated Si(111) was formed in 40% H₄NF and we wished to look for the presence of Si—F or C—F bonds. The silicon region was interesting for what it did not show—no evidence of SiOₓ was observed. The bulk Si peak appears approximately 4 eV lower than the peak for SiOₓ, and these peaks are thus easily separated and analyzed. The inventors looked for SiOₓ since unlike disordered monolayers well-ordered monolayers protect silicon from oxidation. The XPS samples were allowed to sit exposed to atmospheric conditions for 2 to 4 weeks prior to their characterization by XPS. If the monolayers were disordered the silicon surfaces would have oxidized during this time period. The lack of SiOₓ in the XPS spectra indicates that well-ordered monolayers were assembled. The presence of a broad peak for O was consistent with previous results for monolayers assembled from TEMPO-C₁₀ and 1-octadecene. As there are many sources for oxygen including the ether oxygen in A, the three oxygens in TEMPO-C₁₀, and SiOₓ this peak cannot be assigned to a specific molecule.

TABLE 2
XPS and HATR-IR Spectroscopy of Monolayers on Si(111).

| | | | | | | HATR-IR | |
|---|---|---|---|---|---|---|---|
| | | ^{a}XPS Composition (%) | | | | νₐ(CH₂) | νₛ(CH₂) |
| Entry | ^{b}Composition | C | Si | SiOₓ | O | (cm⁻¹) | (cm⁻¹) |
| 1 | CH₂═CH(CH₂)₁₅CH₃ | 60 | 33 | 0 | 7.0 | 2920 | 2851 |
| 2 | CH₂═CH(CH₂)₉O(CH₂)₉CH═CH₂ | 67 | 24 | 0 | 8.9 | 2925 | 2854 |
| 3 | 50% CH₂═CH(CH₂)₁₅CH₃/ | 60 | 26 | 0 | 13 | 2924 | 2852 |
| | 50% CH₂═CH(CH₂)₉O(CH₂)₉CH═CH₂ | | | | | | |
| 4 | 75% CH₂═CH(CH₂)₁₅CH₃/ | 68 | 23 | 0 | 9 | 2924 | 2854 |
| | 25% CH₂═CH(CH₂)₉O(CH₂)₉CH═CH₂ | | | | | | |
| 5 | 83% CH₂═CH(CH₂)₁₅CH₃/ | 67 | 26 | 0 | 7 | 2923 | 2854 |
| | 17% CH₂═CH(CH₂)₉O(CH₂)₉CH═CH₂ | | | | | | |
| 6 | CH₂═CH(CH₂)₉O(CH₂)₁₀CH₃ | ^{c} | ^{c} | ^{c} | ^{c} | 2925 | 2854 |

^{a}These compositions are from high resolution scans. We studied the C(1s), Si(2p), and O(1s) peaks. The peak for SiOₓ appeared at 102 eV in the Si(2p) high resolution scan.
^{b}This column refers to the composition of reagents used to assemble the monolayers. All monolayers were assembled in the presence of 0.1 mole % TEMPO-C₁₀. For monolayers assembled from two components, we list the mole % of each olefin that was used.
^{c}The XPS compositions of this monolayer was not determined.

The C(1s) peak in the XPS spectra of monolayers assembled from 1-octadecene or A showed the presence of a Si—C bond and described the thickness of these monolayers. In a recent publication detailing the XPS characterization of organic monolayers on Si(111), Wallert et al. described the presence of a Si—C peak at binding energies approximately 0.9 eV lower than the main C—C peak (Wallart et al. J. Am. Chem. Soc. 127: 7871-78 (2005)), and outlined how to use the integration of that peak relative to the integration of all carbon in the XPS to find a thickness for the monolayer. The carbon peaks from monolayers assembled from 1-octadecene or A were fitted using the values from Wallert et al. and found the presence of Si—C bonds. The Si—C peak from monolayers assembled only from 1-octadecene integrated to 4.1% of the total amount of carbon. This value gave a thickness for the monolayer of 20 Å which matches the predicted value for the monolayer and agreed well with the previously measured ellipsometric thickness of 18 Å. See, Arafat et al. Chem. Commun. 25: 3198-3200 (2005).

The C(1s) region in the XPS of monolayers assembled from A fit to three different peaks. The largest peak was assigned to the majority of the carbons on the monolayer. A smaller peak at a binding energy of 1.2 eV higher than the largest peak was assigned to the carbons next to the oxygen in A. This peak was not present in monolayers assembled from 1-octadecene as that molecule lacks an ether bond. Finally, a small peak at a binding energy 0.7 eV lower than the main carbon peak was assigned to carbon bonded to silicon. This peak integrated to 2.7 % of the total amount of carbon. Using the method of Wallert et al., this integration yielded a monolayer thickness of 25 Å (Wallert et al., J. Am. Chem. Soc. 127: 7871-78 (2005). This value agrees with predicted thicknesses for these monolayers and provides further evidence that an ordered monolayer was assembled.

The HATR-IR spectrum of a monolayer of 1-octadecene showed two important peaks. The peaks corresponding to the antisymmetric—νₐ(CH₂)—and symmetric—νₛ(CH₂)—stretches for methylene appear at 2920 and 2851 cm⁻¹. These results are significant as the νₐ(CH₂) peak for crystalline monolayers ranges from 2918 to 2920 cm⁻¹ but for disordered monolayers it ranges from 2925 to 2928 cm⁻¹. Similarly, the νₛ(CH₂) peak for crystalline monolayers appears at 2850 cm⁻¹ but for disordered monolayers it appears at 2858 cm⁻¹. The location of νₐ(CH₂) and νₛ(CH₂) peaks within these ranges describes the crystallinity of monolayers. These results indicate that crystalline monolayers were assembled.

Monolayers assembled from A had peaks for νₐ(CH₂) and νₛ(CH₂) at 2925 and 2954 cm⁻¹ (Table 2). This result was surprising as results from XPS indicated that well-ordered monolayers were assembled but results from HATR-IR spectra indicated that the monolayers were disordered. To further investigate this discrepancy mixed monolayers of A and 1-octadecene were assembled. As the ratio of 1-octadecene to A was increased in solutions used for the assembly, the values for νₐ(CH₂) and νₛ(CH₂) decreased and indicated that mixed monolayers were more ordered than those assembled only from A (Table 2, entries 2 through 5). Also a peak for the olefin at approximately 1641 cm⁻¹ was not observed. This peak is typically weak and difficult to observe, it also may have packed on the surface such that it was not IR active. Although this peak was not seen by HATR-IR spectroscopy, it was present. The following sections describe how these monolayers reacted by cross metathesis and ring opening metathesis polymerizations from the olefins on the surface.

The two major differences between A and 1-octadecene are the presence of an ether and second olefin in A. From the literature of monolayers on gold several important characteristics about how molecules with these functional groups assemble into monolayers become apparent (Peanasky et al. Langmuir 14: 113-23 (1998); Wenzel et al. Langmuir 119: 10217-24 (2003); Sinniah et al. J. Phys. Chem. 99: 14500-05 (1995). Ether bonds promote disorder in monolayers as they favor gauche over trans conformations by approximately 0.1 to 0.2 kcal mol⁻¹ (Miwa & Machida, J. Am. Chem. Soc. 111: 7733-39 (1989)). Whitesides et al. studied monolayers on gold assembled from thiols containing ether bonds by IR spectroscopy and observed several unresolved components near the νₐ(CH₂) and νₛ(CH₂) peaks (Laibinis et al. J. Phys. Chem. 99: 7663-76 (1995)). This work indicated, but did not prove, that the monolayer was not a homogeneous distribution of methylenes. Ether bonds are well known to affect the vibrational frequencies of methylenes and that this effect will increase as the tilt angle of the monolayer increases. These effects place shoulders at slightly higher vibrational frequencies for the νₐ(CH₂) and νₛ(CH₂) peaks of a crystalline hydrocarbon and, if the shoulders were not resolved from the νₐ(CH₂) and νₛ(CH₂) peaks, would cause the νₐ(CH₂) and νₛ(CH₂) peaks to appear to shift to higher frequencies. This is important because shoulders were not observed on the νₐ(CH₂) and νₛ(CH₂) peaks in the spectra as expected. Thus, the values for νₐ(CH₂) and νₛ(CH₂) may not be the true values for these peaks.

In contrast, the presence of a terminal olefin on monolayers of HS(CH₂)₉CH═CH₂ on gold do not cause these monolayers to appear disordered (Lee et al. Langmuir 19:8141-43 (2003); Peanasky et al. Langmuir 14: 113-123 (1998)). Therefore, monolayers terminated with olefins can pack into an all trans, crystalline conformation. Of course it is important to note that monolayers on gold assemble through thiols whereas monolayers on silicon assemble through olefins. Thus, the interpretation of the HATR-IR of a diolefin such as A is more complicated as it may bond twice to silicon through both olefins and assemble into a disordered monolayer.

The ether CH₂═CH(CH₂)₉O(CH₂)₁₀CH₃ (B) was synthesized to study whether how the presence of an ether affects the νₐ(CH₂) and νₛ(CH₂) peaks for monolayers on silicon. Monolayers assembled from B in 0.1 mole % TEMPO-C₁₀ appeared disordered by HATR-IR spectroscopy (Table 2, entry 6). This result was surprising and indicated that one internal ether bond or a second olefin may affect the order of a monolayer on silicon. It was not surprising that a second olefin may introduce some disorder as it may bond to the surface twice and increase the disorder, but it was expected that monolayers assembled from B would appear ordered. It is surprising that one ether bond would have such an impact on monolayers on Si(111).

Because of the limitations of HATR-IR spectroscopy, it was not possible to determine if monolayers assembled from A were ordered or disordered. The peaks were broad and the presence of shoulders on the νₐ(CH₂) and νₛ(CH₂) peaks was not determined although Whitesides et al. described their presence on monolayers on Au. The XPS data were consistent with an ordered monolayer, but HATR-IR data were consistent with a disordered monolayer.

Cross Metathesis on Olefin-Terminated SAMs. A simple cross metathesis reaction between two molecules of undecylenic acid was explored to learn which conditions are needed to push the reaction to completion. 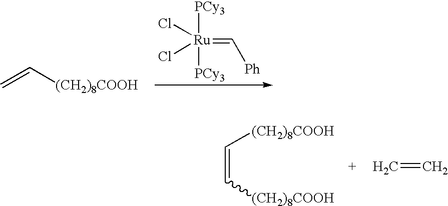
These reactions were stopped after a period of time, the solvent was removed, and the yield was studied by ¹H NMR spectroscopy. Hydrogens on the starting olefin appeared at 5.0 and 5.8 ppm and those on the product appeared at 5.4 ppm; the yield was simple to determine based on this information. Undecylenic acid was chosen for a test reaction as it has a high boiling point that limited its loss under vacuum (boiling point of 137° C. at 2 mm of Hg) and a carboxylic acid. Monolayers functionalized with carboxylic acids are important as they can be readily reacted to expose more complex molecules.

The reaction conditions that were tested are shown in Table 3. Initial attempts in xylene, silicon oil, tetraethylene glycol, and polyethylene glycol were not successful due to poor catalyst solubility. Heating these reactions to speed the reaction or placing them under vacuum to remove ethylene increased the yield but were ultimately unsuccessful. Refluxing methylene chloride was attempted as the catalyst was soluble in this solvent and refluxing helped remove ethylene from the reaction mixture to drive the reaction forward. The yield of this reaction was >97% by ¹H NMR and worked for all olefins that were tested.

TABLE 3
Different Reaction Conditions to Optimize the Cross Metathesis
of 11-Undecylenic Acid.

| ^{a}Amount | | Amount of | ^{b}Grubbs' | | | | |
|---|---|---|---|---|---|---|---|
| of olefin | | solvent | catalyst | Temperature | | Time | ^{c}Yield |
| (mL) | Solvent | (mL) | (mole %) | (° C.) | Vacuum | (h) | (%) |
| 1.36 | Xylenes | 4.5 | 0.32 | 25 | No | 22 | 16 |
| 1.28 | Xylenes | 4.5 | 0.32 | 40 | No | 21 | 23 |
| 1.0 | Xylenes | 3.0 | 1.0 | 40 | No | 41 | 47 |
| 1.0 | Xylenes | 3.0 | 1.0 | 55 | No | 30 | 58 |
| 1.0 | Xylenes | 3.0 | 1.0 | 70 | No | 50 | 91 |
| 1.0 | Xylenes | 3.0 | 1.0 | 85 | No | 72 | 91 |
| 4.3 | None | | 0.32 | 40 | No | 20 | 59 |
| 1.0 | Tetraethylene | 3.0 | 1.0 | 25 | Yes | 46 | 54 |
| | glycol | | | | | | |
| 1.0 | Tetraethylene | 3.0 | 1.0 | 40 | Yes | 19 | 69 |
| | glycol | | | | | | |
| 1.0 | Poly(ethylene | 3.0 | 1.0 | 60 | Yes | 113 | 72 |
| | glycol) 600 | | | | | | |
| | M_{w} | | | | | | |
| 1.0 | Silicon oil | 3.0 | 1.0 | 40 | Yes | 48 | 73 |
| 1.0 | Methylene | 3.0 | 1.0 | Reflux | No | 48 | 100 |
| | chloride | | | | | | |

^{a}Each of these reactions were carried out under an atmosphere of N₂ or under vacuum (approximately 100 millitorr).
^{b}The mole % of catalyst relative to undecylenic acid.
^{c}The yield refers to undecylenic acid that was cross metathesized to ═(CH(CH₂)₈CO₂H)₂.

Cross Metathesis Between Olefin-Terminated Monolayers and Fluorinated Olefins. Although reaction conditions were identified that allow for low catalyst loadings and quantitative cross metathesis reactions, it is important to note that these conditions were for olefins in solution rather than those on monolayers. Olefins exposed on a monolayer may undergo three different reactions when reacted with the Grubbs' catalyst in the presence of an olefin in solution. First, olefin-terminated monolayers may react with olefins in solution and yield functionalized surfaces. Second, olefins on the monolayer may undergo cross metathesis with each other. Third, olefins on the monolayer may be too sterically hindered from reacting with the Grubbs' catalyst. These three possible outcomes complicate interpretation of olefin-terminated monolayers that reacted with the Grubbs' catalyst and an olefin in solution.

To study the yield of cross metathesis on olefins exposed on a monolayer, CH₂═CH(CH₂)₉OCH₂(CF₂)₆CF₃ was synthesized. The fluorines on this molecule provided a unique handle during XPS that could be used to study cross metathesis on monolayers. Monolayers were first assembled on silicon from different ratios of A and 1-octadecene. Next, these monolayers were reacted with the Grubbs' catalyst and CH₂═CH(CH₂)₉OCH₂(CF₂)₆CF₃ in refluxing methylene chloride. Finally, these surfaces were studied by XPS for C, F, Si, and O.

These experiments showed that the highest concentration of fluorine on the surface was observed for monolayers assembled from 50% A and 50% 1-octadecene. Interestingly, monolayers assembled only from A had a lower amount of fluorine on the surface. This result suggests that either cross metathesis between olefins on the monolayer was significant or that the monolayers were too ordered to fully react with the Grubbs' catalyst. For surfaces with decreasing mole fractions of A used in their assembly, the amount of fluorine observed by XPS slowly decreased.

These surfaces were also studied by HATR-IR spectroscopy but the three different outcomes described above could not be distinguished. Due to strong absorptions below 1500 cm⁻¹, HATR-IR spectroscopy on Si(111) shards can not image peaks below this cutoff and the peaks in the C—H region were too broad to distinguish the different olefins that may be present on the surface. Nevertheless, these results are important because the optimal ratio of A to 1-octadecene in solution was identified to functionalize surfaces.

Composition of Mixed Monolayers. It was unclear how the ratio of A to 1-octadecene used in the assembly of monolayers relates to their final composition. For instance, it is not known if a 1/1 molar ratio of A to 1-octadecene in solution results in a 1/1 ratio of these molecules in the monolayer. The previously described studies do not indicate the composition on the surface due to potential cross metathesis between olefins on the monolayers and incomplete cross metathesis between olefins in solution with those on the surface. A cleaner system was needed to study the composition of monolayers assembled from two different molecules.

To learn how the composition of solutions used in the assembly relates to the final composition of monolayers, CH₂═CH(CH₂)₉O(CH₂)₆Cl was synthesized. Monolayers assembled from this molecule will have the same thickness as a monolayer assembled from 1-octadecene and expose a chlorine on the top of the monolayer. By measuring the ratio of chlorine to carbon by XPS for monolayers assembled from mixtures of CH₂═CH(CH₂)₉O(CH₂)₆Cl and 1-octadecene the composition of these monolayers was determined—the ratio of CH₂═CH(CH₂)₉O(CH₂)₆Cl to 1-octadecene in solution closely follows the ratio of these molecules in the monolayer.

Cross Metathesis With Olefins Exposing Useful Functional Groups. As the Grubbs' catalyst is stable in the presence of many functional groups, monolayers displaying a variety of different functional groups can be synthesized. To demonstrate this potential, monolayers assembled from 50% A and 50% 1-octadecene were reacted with olefins terminated with alcohols, bromides, aldehydes, and carboxylic acids. These surfaces were studied by XPS and HATR-IR spectroscopy (Table 4). These results indicated that each monolayer was functionalized with an olefin and exposed different functional groups on the surface.

TABLE 4
Cross Metathesis Between Olefin-Terminated Monolayers and
Functional Olefins in Solution.

| | | | | | | | HATR-IR Spectroscopy | | |
|---|---|---|---|---|---|---|---|---|---|
| | | XPS Composition (%) | | | | | νₐ(CH₂) | νₛ(CH₂) | ν(C═O) |
| Entry | Olefin | C | Si | SiOₓ | F | O | (cm⁻¹) | (cm⁻¹) | (cm⁻¹) |
| 1 | CH₂═CH(CH₂)₈CO₂H | 58 | 22 | 0 | 0 | 20 | 2924 | 2854 | 1739, |
| | | | | | | | | | 1700 |
| 2 | CH₂═CH(CH₂)₉OH | 67 | 23 | 0 | 0 | 10 | 2925 | 2855 | ^{a}1739 |
| 3 | CH₂═CH(CH₂)₈CHO | 68 | 19 | 0 | 0 | 12 | 2925 | 2854 | 1730 |

^{a}After cross metathesis with the monolayer, the alcohol was reacted with acetyl chloride. The carbonyl peaks of the ester are reported.

Patterning Monolayers on the Micrometer Size-Scale Using Soft Lithography. This section describes methods to pattern monolayers on the micrometer-size scale by soft lithography. Specifically, PDMS was patterned on the micrometer-size scale such that a series of microchannels were formed when a PDMS stamp was placed against a silicon wafer. These microchannels were easily accessible by an external syringe pump to add reagents only to the microchannels. Monolayers in contact with PDMS were protected from reaction. Soft lithography was chosen as these techniques have become well accepted in the scientific community, they are used to pattern monolayers on gold, and their applications to form microfluidic channels are becoming increasingly important. Generating patterns by soft lithography is rapid because PDMS stamps are readily manufactured in under 24 h (Qin et al. Adv. Mater. 8: 917-19 (1996).

The method for patterning olefin-terminated monolayers on Si(111) with the Grubbs' catalyst involves, first, assembling a mixed monolayer of A and 1-octadecene. Second, the silicon wafer was immersed in a solution of the Grubbs' first generation catalyst for 15 min. The Grubbs' catalyst attached to the monolayer by cross metathesis with an olefin on the surface. A PDMS stamp was then placed on the monolayer to form microfluidic channels on the surface. Next, a solution of an olefin filled the channels by an external syringe (not shown). Monolayers in contact with PDMS were not exposed to the olefins and did not react. After 15 to 30 min the channels were rinsed, the PDMS stamp was removed and turned 90° before being placed on the monolayer again. A new solution of an olefin added to the channels. Finally, the channels were rinsed, the PDMS stamp was removed, and the silicon wafer was rinsed.

Our general method is outlined in FIG. 13. To demonstrate this method monolayers were patterned through cross metathesis and ring opening polymerizations (ROMP). In a one example polymer brushes were grown from the surfaces using ROMP as the Grubbs' catalyst polymerizes strained monomers under living conditions. Polymer brushes of 5-norbornene-2-carboxylic acid were synthesized as it polymerizes rapidly and exposes carboxylic acids on the surface (FIG. 13b). These polymer brushes were covalently attached to the surface and could not be washed from the surface.

In a second example monolayers were patterned by cross metathesis using solutions of CH₂═CH(CH₂)₈CO₂H (FIGS. 13c and d). These methods demonstrate that monolayers can be patterned using either cross metathesis or ROMP.

This work shows the assembly and characterization of monolayers of A, the cross metathesis of olefin-terminated monolayers on Si(111), and the patterning of these monolayers using ROMP and cross metathesis. This Example demonstrated that exposed alkyl bromides, aldehydes, carboxylic acids, and alcohols can be patterned and provides methods showing how these surfaces may be patterned. These functional groups can be used a linkage points for attachment of DNA, proteins, and other important molecules. Thus, the methods described herein are applicable to the complex functionalization of monolayers on silicon.

### REFERENCES

(1) (a) Sieval, A. B.; Linke, R.; Zuilhof, H.; Sudhölter, E. J. R. Adv. Mater. 2000, 12, 1457-1460. (b) Cicero, R. L.; Linford, M. R.; Chidsey, C. E. D. Langmuir 2000, 16, 5688-5695. (c) Hovis, J. S.; Liu, H.; Hamers, R. S. Surface Science 1998, 402-404, 1-7. (d) Barrelet, C. J.; Robinson, D. B.; Cheng, J.; Hunt, T. P.; Quate, C. F.; Chidsey, C. E. D. Langmuir 2001, 17, 3460-3465. (e) Buriak, J. M.; Allen, M. J. J. Am. Chem. Soc. 1998, 120, 1339-1340. (f) Bateman, J. E.; Eagling, R. D.; Worrall, D. R.; Horrocks, B. R.; Houlton, A. Angew. Chem. Int. Ed. 1998, 37, 2683-2685.

(2) Bansal, A.; Li, X.; Yi, S. I.; Weinberg, W. H.; Lewis, N. S. J. Phys. Chem. B 2001, 105, 10266-10277.

(3) (a) Linford, M. R.; Chidsey, C. E. D. Langmuir 2002, 18, 6217-6221. (b) Niederhauser, T. L.; Lua, Y.-Y.; Jiang, G.; Davis, S. D.; Matheson, R.; Hess, D. A.; Mowat, I. A.; Linford, M. R. Angew. Chem. Int. Ed. 2002, 41, 2353-2356. (c) Wojtyk, J. T. C.; Tomietto, M.; Boukherroub, R.; Wayner, D. D. M. J. Am. Chem. Soc. 2001, 123, 1535-1536. (d) Bent, S. F. J. Phys.

Chem. B 2002, 106, 2830-2842.

(4) Linford, M. R.; Fenter, P.; Eisenberger, P. M.; Chidsey, C. E. D. J. Am. Chem. Soc. 1995, 117, 3145-3155.

(5) (a) Wade, C. P.; Chidsey, C. E. D. Appl. Phys. Lett. 1997, 71, 1679-1681. (b) Higashi, G. S.; Chabal, Y. J.; Trucks, G. W.; Raghavachari, K. Appl. Phys. Lett. 1990, 56, 656-658.

(6) Thiols on gold are the best studied SAMs; well-ordered SAMs on gold yield advancing contact angles of water of 114° to 115°. Monolayers on gold pack differently than those on silicon; thus, contact angles of water on SAMs on gold should be interpreted carefully when comparing them to measurements on other surfaces.

(7) (a) Holmes-Farley, S. R.; Whitesides, G. M. Langmuir 1987, 3, 62-76. (b) Holmes-Farley, S. R.; Reamey, R. H.; McCarthy, T. J.; Deutch, J.; Whitesides, G. M. Langmuir 1985, 1, 725-740.

(8) Pitters, J. L.; Piva, P. G.; Tong, X.; Wolkow, R. A. Nano Lett. 2003, 3, 1431-1435.

(1) (a) Wayner, D. D. M.; Wolkow, R. A. J. Chem. Soc., Perkin Trans. 2002, 2, 23-34; (b) Li, X.-M.; Huskens, J.; Reinhoudt, D. N. J. Mater. Chem. 2004, 14, 2954-2971; (c) Sieval, A. B.; Vleeming, V.; Zuilhof, H.; Sudholter, E. J. R. Langmuir 1999,15, 8288-8291; (d) Zhu, X.-Y.; Jun, Y.; Staarup, D. R.; Major, R. C.; Danielson, S.; Boiadjiev, V.; Gladfelter, W. L.; Bunker, B. C.; Guo, A. Langmuir 2001, 17, 7798-7803; (e) Bergerson, W. F.; Mulder, J. A.; Hsung, R. P.; Zhu, X.-Y. J. Am. Chem. Soc. 1999, 121, 454-455; (f) Boukherroub, R.; Wayner, D. D. M. J. Am. Chem. Soc. 1999, 121, 11513-11515; (g) Kim, N. Y.; Laibinis, P. E. J. Am. Chem. Soc. 1997, 199, 2297-2298; (h) Kim, N. Y.; Laibinis, P. E. J. Am. Chem. Soc. 1998, 120, 4516-4517; (i) Zhang, L.; Wesley, K.; Jiang, S. Langmuir 2001, 17, 6275-6281; (j) Uosaki, K.; Quayum, M. E.; Nihonyanagi, S.; Kondo, T. Langmuir 2004, 20, 1207-1212; (k) Bansal, A.; Li, X.; Lauermann, I.; Lewis, N. S. J. Am. Chem. Soc. 1996, 118, 7225-7226; (1) Bansal, A.; Li, X.; Yi, S. I.; Weinberg, W. H.; Lewis, N. S. J. Phys. Chem. B 2001, 105, 10266-10277; (m) Sung, M. M.; Kluth, G. J.; Yauw, O. W.; Maboudian, R. Langmuir 1997, 13, 6164-6168; (n) Buriak, J. M. Chem. Commun. 1999, 12, 1051-1060; (o) Buriak, J. M.; Allen, M. J. J. Am. Chem. Soc. 1998,120, 1339-1340; (p) Liu, Y.-J.; Navasero, N. M.; Yu, H.-Z. Langmuir 2004, 20, 4039-4050; (q) Sun, Q.-Y.; De Smet, L. C. P. M.; Van Lagen, B.; Giesbers, M.; Thuene, P. C.; Van Engelenburg, J.; De Wolf, F. A.; Zuilhof, H.; Sudhoelter, E. J. R. J. Am. Chem. Soc. 2005, 127, 2514-2523; ( r) Sun, Q.-Y.; de Smet, L. C. P. M.; van Lagen, B.; Wright, A.; Zuilhof, H.; Sudhoelter, E. J. R. Angew. Chem. Int. Ed. 2004, 43, 1352-1355.

(2) (a) Li, Y. J.; Tero, R.; Nagasawa, T.; Ngata, T.; Urisu, T. Appl. Surface Sci. 2004, 238, 238-241; (b) Boukherroub, R.; Morin, S.; Bensebaa, F.; Wayner, D. D. M. Langmuir 1999, 15, 3831-3835.

(3) Sieval, A. B.; Demirel, A. L.; Nissink, J. W. M.; Linford, M. R.; van der Maas, J. H.; de Jeu, W. H.; Zuilhof, H.; Sudholter, E. J. R. Langmuir 1998, 14, 1759-1768.

(4) Sieval, A. B.; Linke, R.; Zuilhof, H.; Sudhölter, E. J. R. Adv. Mater. 2000, 12, 1457-1460.

(5) (a) Linford, M. R.; Chidsey, C. E. D. Langmuir 2002, 18, 6217-6221; (b) Linford, M. R.; Fenter, P.; Eisenberger, P. M.; Chidsey, C. E. D. J. Am. Chem. Soc. 1995,117, 3145-3155.

(6) (a) de Smet, L. C. P. M.; Stork, G. A.; Hurenkamp, G. H. F.; Sun, Q.-Y.; Topal, H.; Vronen, P. J. E.; Sieval, A. B.; Wright, A.; Visser, G. M.; Zuilhof, H.; Sudhoelter, E. J. R. J. Am. Chem. Soc. 2003, 125, 13916-13917; (b) de Smet, L. C. P. M.; Pukin, A. V.; Stork, G. A.; Ric de Vos, C. H.; Visser, G. M.; Zuilhof, H.; Sudhoelter, E. J. R. Carbohydr. Res. 2004, 339, 2599-2605; (c) Ara, M.; Tada, H. Appl. Phys. Lett. 2003, 83, 578-580; Lasseter, T. L.; Clare, B. H.; Abbott, N. L.; Hamers, R. S. J. Am. Chem. Soc. 2004, 126, 10220-10221; (d) Liao, W.; Wei, F.; Qian, M. X.; Zhao, X. S. Sens. Actuators, B 2004, B101, 361-367.

(7) (a) Strother, T.; Cai, W.; Zhao, X.; Hamers, R. J.; Smith, L. M. J. Am. Chem. Soc. 2000, 122, 1205-1209; (b) Voicu, R.; Boukherroub, R.; Bartzoka, V.; Ward, T.; Wojtyk, J. T. C.; Wayner, D. D. M. Langmuir 2004, 20, 11713-11720.

(8) Pike, A. R.; Lie, L. H.; Eagling, R. A.; Ryder, L. C.; Patole, S. N.; Connolly, B. A.; Horrocks, B. R.; Houlton, A. Angew. Chem. Int. Ed. 2002, 41, 615-617.

(9) (a) Burrows, V. A.; Chabal, Y. J.; Higashi, G. S.; Raghavachari, K.; Christman, S. B. Appl. Phys. Lett. 1988, 53, 998-1000; (b) Wade, C. P.; Chidsey, C. E. D. Appl. Phys. Lett. 1997, 71, 1679-1681.

(10) Higashi, G. S.; Chabal, Y. J.; Trucks, G. W.; Raghavachari, K. Appl. Phys. Lett. 1990, 56, 656-658.

(11) Perring, M.; Dutta, S.; Arafat, S.; Mitchell, M.; Kenis, P. J. A.; Bowden, N. B. Langmuir 2005, In Press.

(12) Arafat, S. N.; Dutta, S.; Perring, M.; Mitchell, M.; Kenis, P. J. A.; Bowden, N. B. Chem. Commun. 2005, 25, 3198-3200.

(13) (a) Cattaruzza, F.; Cricenti, A.; Flamini, A.; Girasole, M.; Longo, G.; Mezzi, A.; Prosperi, T. J. Mater. Chem. 2004, 14, 1461-1468; (b) Cai, W.; Peck, J. R.; van der Weide, D. W.; Hamers, R. J. Biosens. Bioelectron. 2004, 19, 1013-1019.

(14) (a) Jiang, G.; Niederhauser, T. L.; Davis, S. D.; Lua, Y.-Y.; Cannon, B. R.; Dorff, M. J.; Howell, L. L.; Magleby, S. P.; Linford, M. R. Colloids Surf, A 2003, 226, 9-16; (b) Lua, Y.-Y.; Fillmore, W. J. J.; Linford, M. R. Appl. Surf. Sci. 2004, 231-232, 323-327; (c) Niederhauser, T. L.; Lua, Y.-Y.; Jiang, G.; Davis, S. D.; Matheson, R.; Hess, D. A.; Mowat, I. A.; Linford, M. R. Angew. Chem. Int. Ed. 2002, 41, 2353-2356; (d) Wagner, P.; Nock, S.; Spudich, J. A.; Volkmuth, W. D.; Chu, S.; Cicero, R. L.; Wade, C. P.; Linford, M. R.; Chidsey, C. E. D. J. Struct. Biol. 1997, 119, 189-201.

(15) (a) Liu, Z.; Rainier, J. D. Org. Lett. 2005, 7, 131-133; (b) Bielawski, C. W.; Grubbs, R. H. Macromolecules 2001, 34, 8838-8840; (c) Sanford, M. S.; Love, J. A.; Grubbs, R. H. J. Am. Chem. Soc. 2001, 123, 6543-6554; (d) Schwab, P.; Grubbs, R. H.; Ziller, J. W. J. Am. Chem. Soc. 1996, 118, 100-110; (e) Trnka, T. M.; Grubbs, R. H. Accts. Chem. Res. 2001, 34, 18-29; (f) Blackwell, H. E.; O'Leary, D. J.; Chatterjee, A. K.; Washenfelder, R. A.; Bussmann, D. A.; Grubbs, R. H. J. Am. Chem. Soc. 2000, 122, 58-71; (g) Sanford, M. S.; Henling, L. M.; Day, M. W.; Grubbs, R. H. Angew. Chem. Int. Ed. 2000, 39, 3451-3453; (h) Connon, S. J.; Blechert, S. Angew. Chem. Int. Ed. 2003, 42, 1900-1923; (i) Schmidt, B. Angew. Chem. Int. Ed. 2003, 42, 4996-4999.

(16) (a) Liu, X.; Guo, S.; Mirkin, C. A. Angew. Chem. Int. Ed. 2003, 42, 4785-4789; (b) Li, X.-M.; Huskens, J.; Reinhoudt, D. N. Nanotechnology 2003, 14, 1064-1070; (c) Harada, Y.; Girolami, G. S.; Nuzzo, R. G. Langmuir 2003, 19, 5104-5114; (d) Rutenberg, I. M.; Scherman, 0. A.; Grubbs, R. H.; Jiang, W.; Garfunkel, E.; Bao, Z. J. Am. Chem. Soc. 2004, 126, 4062-4063; (e) Watson, K. J.; Zhu, J.; Nguyen, S. T.; Mirkin, C. A. J. Am. Chem. Soc. 1999, 121, 462-463; (f) Jeon, N. L.; Choi, I. S.; Whitesides, G. M.; Kim, N. Y.; Laibinis, P. E.; Harada, Y.; Finnie, K. R.; Girolami, G. S.; Nuzzo, R. G. Appl. Phys. Lett. 1999, 75, 4201-4203; (g) Weck, M.; Jackiw, J. J.; Rossi, R. R.; Weiss, P. S.; Grubbs, R. H. J. Am. Chem. Soc. 1999, 121, 4088-4089; (h) Jordi, M. S.; Seery, T. A. P. J. Am. Chem. Soc. 2005, 127, 4416-4422; (i) Gomez, F. J.; Chen, R. J.; Wang, D.; Waymouth, R. M.; Dai, H. Chem. Commun. 2003, 190-191; (j) Agnes, J.; Scherman, O. A.; Grubbs, R. H.; Lewis, N. S. Langmuir 2001, 17, 1321-1323; (k) Kim, N. Y.; Jeon, N. L.; Choi, I. S.; Takami, S.; Harada, Y.; Finnie, K. R.; Girolami, G. S.; Nuzzo, R. G.; Whitesides, G. M.; Laibinis, P. E. Macromolecules 2000, 33, 2793-2795.

(17) Lee, J. K.; Lee, K.-B.; Kim, D. J.; Choi, I. S. Langmuir 2003, 19, 8141-8143.

(18) Cicero, R. L.; Linford, M. R.; Chidsey, C. E. D. Langmuir 2000, 16, 5688-5695.

(19) Wallart, X.; de Villeneuve, C. H.; Allongue, P. J. Am. Chem. Soc. 2005, 127, 7871-7878.

(20) (a) Porter, M. D.; Bright, T. B.; Allara, D. L.; Chidsey, C. E. D. J. Am. Chem. Soc. 1987, 109, 3559-3568; (b) Snyder, R. G.; Strauss, H. L.; Elliger, C. A. J. Phys. Chem. 1982, 86, 5145-5150.

(21) Dubowski, Y.; Vieceli, J.; Tobias, D. J.; Gomez, A.; Lin, A.;

Nizkoorodor, S. A.; Mcintire, T. M.; Finlayson-Pitts, B. J. J. Phys. Chem. A 2004, 108, 10473-10485.

(22) Peanasky, J. S.; McCarley, R. L. Langmuir 1998, 14, 113-123.

(23) (a) Wenzel, I.; Yam, C. M.; Barriet, D.; Lee, T. R. Langmuir 2003, 119, 10217-10224; (b) Sinniah, K.; Cheng, J.; Terrettaz, S.; Reutt-Robey, J. E.; Miller, C. J. J. Phys. Chem. 1995, 99, 14500-14505.

(24) Laibinis, P. E.; Bain, C. D.; Nuzzo, R. G.; Whitesides, G. M. J. Phys. Chem. 1995, 99, 7663-7676.

(25) Miwa, Y.; Machida, K. J. Am. Chem. Soc. 1989,111, 7733-7739.

(26) (a) Aizenberg, J. Adv. Mater. 2004, 16, 1295-1302; (b) Bruinink, C. M.; Peter, M.; de Boer, M.; Kuipers, L.; Huskens, J.; Reinhoudt, D. N. Adv. Mater. 2004, 16, 1086-1090; (c) Kane, R. S.; Stroock, A. D.; Jeon, N. L.; Ingber, D. E.; Whitesides, G. M. Opt. Biosens. 2002, 571-595; (d) Kane, R. S.; Takayama, S.; Ostuni, E.; Ingber, D. E.; Whitesides, G. M. Biomaterials 1999, 20, 2363-2376; (e) Lee, C. J.; Blumenkranz, M. S.; Fishman, H. A.; Bent, S. F. Langmuir 2004, 20, 4155-4161; (f) McDonald, J. C.; Duffy, D. C.; Anderson, J. R.; Chiu, D. T.; Wu, H.; Schueller, O. J.; Whitesides, G. M. Electrophoresis 2000, 21, 27-40; (g) Rolland, J.; Hagberg, E. C.; Dension, G. M.; Carter, K. R.; De Simone, J. M. Angew. Chem. Int. Ed. 2004, 43, 5796-5799; (h) Whitesides, G. M.; Ostuni, E.; Takayama, S.; Jiang, X.; Ingber, D. E. Ann. Rev. Biomed. Eng. 2001, 3, 335-373; (i) Xia, Y.; Whitesides, G. M. Angew. Chem. Int. Ed. 1998, 37, 550-575.

(27) Qin, D.; Xia, Y.; Whitesides, G. M. Adv. Mater. 1996, 8, 917-919.

All patents and publications referenced or mentioned herein are indicative of the levels of skill of those skilled in the art to which the invention pertains, and each such referenced patent or publication is hereby incorporated by reference to the same extent as if it had been incorporated by reference in its entirety individually or set forth herein in its entirety. Applicants reserve the right to physically incorporate into this specification any and all materials and information from any such cited patents or publications.

The specific methods and compositions described herein are representative of preferred embodiments and are exemplary and not intended as limitations on the scope of the invention. Other objects, aspects, and embodiments will occur to those skilled in the art upon consideration of this specification, and are encompassed within the spirit of the invention as defined by the scope of the claims. It will be readily apparent to one skilled in the art that varying substitutions and modifications may be made to the invention disclosed herein without departing from the scope and spirit of the invention. The invention illustratively described herein suitably may be practiced in the absence of any element or elements, or limitation or limitations, which is not specifically disclosed herein as essential. The methods and processes illustratively described herein suitably may be practiced in differing orders of steps, and that they are not necessarily restricted to the orders of steps indicated herein or in the claims. As used herein and in the appended claims, the singular forms “a,” “an,” and “the” include plural reference unless the context clearly dictates otherwise. Thus, for example, a reference to “an antibody” includes a plurality (for example, a solution of antibodies or a series of antibody preparations) of such antibodies, and so forth. Under no circumstances may the patent be interpreted to be limited to the specific examples or embodiments or methods specifically disclosed herein. Under no circumstances may the patent be interpreted to be limited by any statement made by any Examiner or any other official or employee of the Patent and Trademark Office unless such statement is specifically and without qualification or reservation expressly adopted in a responsive writing by Applicants.

The terms and expressions that have been employed are used as terms of description and not of limitation, and there is no intent in the use of such terms and expressions to exclude any equivalent of the features shown and described or portions thereof, but it is recognized that various modifications are possible within the scope of the invention as claimed. Thus, it will be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

The invention has been described broadly and generically herein. Each of the narrower species and subgeneric groupings falling within the generic disclosure also form part of the invention. This includes the generic description of the invention with a proviso or negative limitation removing any subject matter from the genus, regardless of whether or not the excised material is specifically recited herein.

Other embodiments are within the following claims. In addition, where features or aspects of the invention are described in terms of Markush groups, those skilled in the art will recognize that the invention is also thereby described in terms of any individual member or subgroup of members of the Markush group.

What is claimed:

1. A layered silicon surface generated by a method that comprises: obtaining a silicon surface comprising hydrogen-terminated silicon, and reacting the silicon surface with an anchor molecule in the presence of a sterically hindered free radical source under conditions sufficient to link the anchor molecule to the silicon surface.

2. The silicon surface of claim 1, wherein the anchor molecule is an alkene, olefin, olefin ether, alkenethiol, oligo(ethylene)glycol or a combination thereof.

3. The silicon surface of claim 1, wherein the anchor molecule has a functional group that can be used for attachment of a selected ligand.

4. The silicon surface of claim 3, wherein the functional group is generated by cross metathesis between olefin-terminated anchor molecules.

5. The silicon surface of claim 1, wherein the functional group is protected with a protecting group during reaction of the silicon surface with the anchor molecule in the presence of the sterically hindered free radical.

6. The silicon surface of claim 3, wherein the selected ligand is a polypeptide, nucleic acid, peptide, peptidomimetic, antibody, antigen, receptor, receptor ligand, small molecule or drug.

7. The silicon surface of claim 3, wherein the selected ligand is linked to the anchor molecule.

8. The silicon surface of claim 3, wherein the selected ligand is linked to a linker that is attached to the anchor molecule.

9. The silicon surface of claim 1, wherein the sterically hindered free radical source is of the formula: 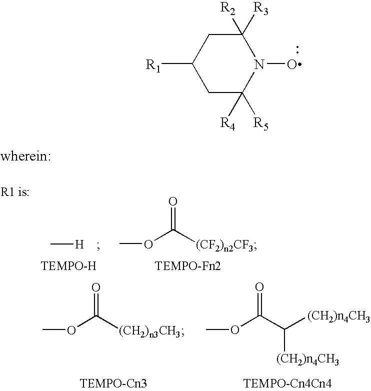
R₂, R₃, R₄ and R₅ are separately lower alkyl;
n1 is an integer of 1 to 20;
n2 is an integer of 1 to 20;
n3 is an integer of 1 to 20; and
each n4 is separately an integer of 1 to 20.

10. A silicon surface linked to hydrogen atoms and an ordered layer of anchor molecules.

11. A layered silicon surface comprising hydrogen-terminated silicon and at least one ordered monolayer of anchor molecules, wherein the ordered monolayer has a contact angle of at least 100°.

12. The surface of claim 10, wherein the anchor molecules are alkenes, olefins, olefin ethers, alkenethiols, oligo(ethylene)glycols or a combination thereof.

13. The surface of claim 10, wherein the anchor molecules are alkanes and olefin ethers.

14. The surface of claim 10, wherein the anchor molecules have a functional group that can be used for attachment of a selected ligand.

15. The surface of claim 14, wherein the functional group is generated by cross metathesis between olefin-terminated anchor molecules.

16. The surface of claim 14, wherein the functional group is protected with a protecting group during reaction of the silicon surface with the anchor molecules in the presence of a sterically hindered free radical source.

17. The surface of claim 10, wherein some of the anchor molecules comprise a selected ligand.

18. The surface of claim 17, wherein the selected ligand is a polypeptide, nucleic acid, peptide, peptidomimetic, antibody, antigen, receptor, receptor ligand, small molecule or drug.

19. The surface of claim 17, wherein the selected ligand is linked to the anchor molecule.

20. The surface of claim 17, wherein the selected ligand is linked to a linker that is attached to the anchor molecule.

21. The surface of claim 10, wherein the anchor molecules are linked to the surface by use of a sterically hindered free radical source.

22. The surface of claim 21, wherein the sterically hindered source is of the formula: 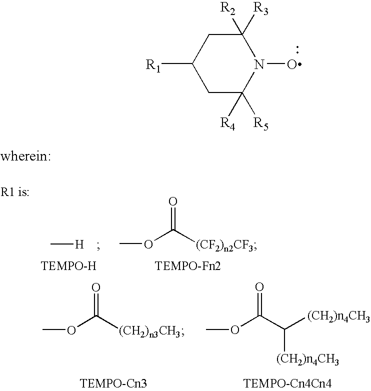
R₂, R₃, R₄ and R₅ are separately lower alkyl;
n1 is an integer of 1 to 20;
n2 is an integer of 1 to 20;
n3 is an integer of 1 to 20; and
each n4 is separately an integer of 1 to 20.

23. The surface of claim 21, wherein the sterically hindered free radical source is 2,2,6,6-tetramethyl-1-piperidinyloxy (TEMPO).

24. The surface of claim 10, wherein the surface is linked to the anchor molecule at room temperature.

25. The surface of claim 10, wherein the surface has a pattern of ligands.

26. The surface of claim 25, wherein the ligands are polypeptides, nucleic acids, peptides, peptidomimetics, antibodies, antigens, receptors, receptor ligands, small molecules or drugs.

27. A method comprising obtaining a silicon surface comprising hydrogen-terminated silicon, reacting the silicon surface with an anchor molecule in the presence of a sterically hindered free radical source under conditions sufficient to link the anchor molecule to the silicon surface.

28. The method of claim 27, wherein the anchor molecule is an alkene, olefin, olefin ether, diolefin ether, alkenethiol, oligo(ethylene)glycol or a combination thereof.

29. The method of claim 27, wherein the anchor molecule has a functional group that can be used for attachment of a selected ligand.

30. The surface of claim 29, wherein the functional group is generated by cross metathesis between olefin-terminated anchor molecules.

31. The method of claim 27, wherein the functional group is protected with a protecting group during reaction of the silicon surface with the anchor molecule in the presence of the sterically hindered free radical.

32. The method of claim 27, wherein the selected ligand is a polypeptide, nucleic acid, peptide, peptidomimetic, antibody, antigen, receptor, receptor ligand, small molecule or drug.

33. The method of claim 27, wherein the selected ligand is linked to the anchor molecule.

34. The method of claim 27, wherein the selected ligand is linked to a linker that is attached to the anchor molecule.

35. The method of claim 27, wherein the sterically hindered free radical source is: 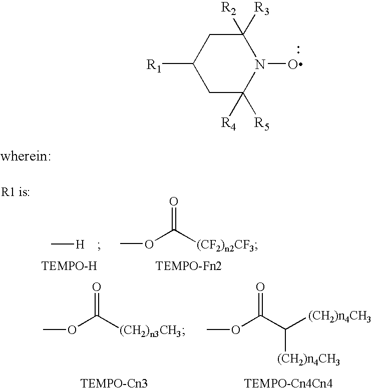
R₂, R₃, R₄ and R₅ are separately lower alkyl;
n1 is an integer of 1 to 20;
n2 is an integer of 1 to 20;
n3 is an integer of 1 to 20; and
each n4 is separately an integer of 1 to 20.

36. A method comprising obtaining a silicon Si(111)-H surface, reacting the silicon Si(111)-H surface with alkene and diolefin ether anchor molecules in the presence of 2,2,6,6-tetramethyl-1-piperidinyloxy (TEMPO) under conditions sufficient to link the anchor molecules to the silicon Si(111)-H surface.

37. The method of claim 36, which further comprises cross metathesis between olefin-terminated anchor molecules to generate a functional group on the anchor molecules or to attach a ligand to the anchor molecules.

38. The method of claim 37, wherein cross metathesis is catalyzed by benzylidene-bis(tricyclohexylphosphine) dichlororuthenium.

39. A compound of the formula: 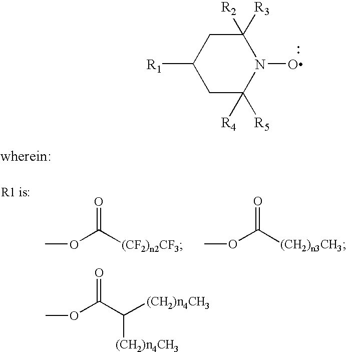
R₂, R₃, R₄ and R₅ are separately lower alkyl;
n1 is an integer of 1 to 20;
n2 is an integer of 1 to 20;
n3 is an integer of 1 to 20; and
each n4 is separately an integer of 1 to 20.

40. A compound of the formula: [chemical structure]
